(19) United States
(12) Patent Application Publication
(10) Pub. No.: US 2026/0353977 A1
(43) Pub. Date: Nov. 5, 2026

(54) DISPLAY DEVICE

(71) Applicant: LG Display Co., Ltd., Seoul (KR)

(72) Inventors: Miji LEE, Paju-si (KR); Hyungoog CHO, Paju-si (KR); Jeonghwan KIM, Paju-si (KR); Minseon PARK, Paju-si (KR); Sanghee YU, Paju-si (KR); Indeock HONG, Paju-si (KR); Bokyoung KIM, Paju-si (KR); Junho ROH, Paju-si (KR)

(73) Assignee: LG Display Co., Ltd., Seoul (KR)

(21) Appl. No.: 19/566,631

(22) Filed: Mar. 13, 2026

(30) Foreign Application Priority Data
Apr. 30, 2025 (KR) 10-2025-0057318

(51) Int. Cl. H10K 59/80; H10K 59/12; H10K 59/122; H10K 59/131

(52) U.S. Cl. CPC H10K 59/80521; H10K 59/1201; H10K 59/122; H10K 59/131; H10K 59/80522

(57) ABSTRACT

A display device may include: a substrate; an anode electrode formed on the substrate and patterned in correspondence with a plurality of pixels; a connection electrode formed on the substrate and electrically connected to a low potential driving voltage; a bank formed on the anode electrode and the connection electrode and exposing at least one region of the anode electrode; an emission layer disposed on the anode electrode; a cathode electrode formed on the emission layer; an overhang structure layer disposed on the bank and comprising a lower layer and an upper layer; and a cathode connection overlapping the overhang structure layer and configured to electrically connect the cathode electrode and the connection electrode to each other.

### CROSS REFERENCE TO RELATED APPLICATION

The present application claims priority to Korea Patent Application No. 10-2025-0057318, filed Apr. 30, 2025, the entire contents of which is incorporated herein for all purposes by this reference.

### BACKGROUND

### Technical Field

The present disclosure relates to a display device, and particularly relates to a display device forming a light emitting element through evaporation deposition using an overhang structure.

### Discussion of the Related Art

A display device is configured to display an image using pixels disposed on a display panel. The use of the display device has increased in more applications, and the display devices have been utilized so as to be manufactured to be used in more electronic devices. Accordingly, a display device capable of being implemented in an ultra-thin shape while having higher resolution and display quality is required recently.

A process for patterning the pixels on the display panel may limit a size and a resolution of the display panel. In case of a process utilizing a fine metal mask, a size of the display panel is increased more and reduces the resolution compared to a case of utilizing photolithography. In addition, after the patterning process, when a lift-off process for an organic material is required, an organic particle which interferes with performance of the display device may remain.

As a result, a structure of a display device and a method for manufacturing the same which increases the number of the pixels per inch and provides improved display performance is required. SUMMARY Accordingly, embodiments of the present disclosure are directed to a display device that substantially obviates one or more of the problems due to limitations and disadvantages of the related art.

An aspect of the present disclosure is to provide a display device forming a light emitting element through evaporation deposition using an overhang structure.

Another aspect of the present disclosure is to provide a display device of which a common layer and an emission layer are separated per pixel through the overhang structure layer, and electrically connecting a cathode electrode and a low potential driving voltage line to each other through a structure in which the cathode electrode and the auxiliary cathode electrode contact each other.

Another aspect of the present disclosure is to provide a display device having a stripe arrangement, of which pixels emitting in colors different from one another are sequentially and alternately disposed along a row direction (e.g., a horizontal direction), and pixels emitting the same color are disposed along a column direction (e.g. a vertical direction), and in which an overhang structure layer is disposed between the pixel columns adjacent to each other.

Another aspect of the present disclosure is to provide a display device in which an auxiliary cathode connection overlapping the overhang structure layer and electrically connecting the auxiliary cathode electrode and the low potential driving voltage line to each other is formed.

Another aspect of the present disclosure is to provide a display device of which the auxiliary cathode connection is elongated between the pixel columns adjacent to each other in the column direction (e.g. a vertical direction), or in which the auxiliary cathode connection is formed in an island form.

Another aspect of the present disclosure is to provide a display device in which a bank patterned in a form in which an upper surface thereof protrudes or is recessed is formed between the pixel rows adjacent to each other, when the pixels are disposed in a stripe shape.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate; an anode electrode formed on the substrate and patterned in correspondence with a plurality of pixels; a connection electrode formed on the substrate and electrically connected to a low potential driving voltage; a bank formed on the anode electrode and the connection electrode and exposing at least one region of the anode electrode; an emission layer disposed on the anode electrode; a cathode electrode formed on the emission layer; an overhang structure layer disposed on the bank and comprising a lower layer and an upper layer; and a cathode connection overlapping the overhang structure layer and configured to electrically connect the cathode electrode and the connection electrode to each other.

The display device may further include: an auxiliary cathode electrode interposed between the bank and the overhang structure layer and having at least one region connected to the cathode electrode.

The auxiliary cathode electrode may be connected to the connection electrode through a contact hole formed on the bank on a cathode connection.

The plurality of pixels may be disposed in a stripe form, and the overhang structure layer may be formed in a shape extending between pixel columns adjacent to each other along a pixel column direction.

The cathode connection may be formed in a shape extending between the pixel columns adjacent to each other along the pixel column direction.

The cathode connection may be formed in an island form between the pixel columns adjacent to each other.

The overhang structure layer may have a first width between the pixel columns adjacent to each other and extend along the pixel column direction, and the overhang structure layer may have a second width greater than the first width in a region overlapping the cathode connection.

The bank may include a pattern portion in which at least one pattern formed by protruding from or being recessed on an upper surface is formed.

The bank may be formed in a shape extending between pixel rows adjacent to each other and between pixel columns adjacent to each other, and the pattern portion may be formed in a shape extending between the pixel rows adjacent to each other.

The plurality of pixels may be disposed in a dot form, and the overhang structure layer may be formed to surround each of the pixels.

The cathode connection may be formed in an elongated shape extending between a plurality of pixels.

The plurality of pixels may be divided into a plurality of unit pixels, each of which including pixels emitting in a color different from one another, and one the cathode connection may be disposed in every unit pixel.

The lower layer may be formed of a conductive inorganic material, and come into contact with the connection electrode through a contact hole formed on the bank on the cathode connection.

The cathode connection may be formed such that at least one region thereof comes into contact with the lower layer.

A lower surface of the upper layer may protrude more outward than an upper surface of the lower layer.

In another aspect, a display device comprises a plurality of pixels disposed on a substrate; a bank formed on the substrate and configured to define an emission region of each of the plurality of pixels; an overhang structure layer formed on the bank; and a connection electrode overlapping the overhang structure layer and electrically connected to a low potential driving voltage; and an auxiliary cathode electrode interposed between the bank and the overhang structure layer and in contact with the connection electrode through a contact hole formed on the bank on the cathode connection.

Each of the plurality of pixels may include: an anode electrode; an emission layer disposed on the anode electrode; and a cathode electrode disposed on the emission layer and electrically connected to the low potential driving voltage through the auxiliary cathode electrode.

The plurality of pixels may be disposed in a stripe form, and the cathode connection may be formed in a stripe form extending between pixel columns adjacent to each other along a pixel column direction, or in an island form between the pixel columns adjacent to each other.

When the cathode connection is formed in the island form, the overhang structure layer may have a first width between the pixel columns adjacent to each other, extends along the pixel column direction, and may have a second width greater than the first width on the cathode connection.

The bank may include a pattern portion in which at least one pattern formed by protruding from or being recessed on an upper surface is formed.

The plurality of pixels may be disposed in a dot form, and the overhang structure layer may be formed to surround each of the pixels.

The cathode connection may be formed in an elongated shape extending between a plurality of pixels.

The plurality of pixels may be divided into a plurality of unit pixels, each of which including pixels emitting in a color different from one another, and one the cathode connection may be disposed in every unit pixel.

In another aspect, a display device comprises a substrate; a plurality of pixels disposed on the substrate in a stripe form; a connection electrode formed on the substrate and electrically connected to a low potential driving voltage; a bank formed on the substrate and configured to expose an emission region of each of the plurality of pixels; and an overhang structure layer formed on the bank; wherein the bank comprises a pattern portion extended in a first direction; wherein the overhang structure layer is configured to extend between adjacent pixels among the plurality of pixels in a second direction perpendicular to the first direction, and intersects the pattern portion.

In another aspect, a display device comprises a substrate; a plurality of pixels disposed on the substrate, the boundaries of at least some pixels of the plurality of pixels are defined by an overhang structure layer; a bank formed on the substrate and configured to expose an emission region of each of the plurality of pixels; a first electrode, an emission layer and a second electrode successively formed on the substrate in the emission region; wherein the overhang structure layer comprises a first portion formed above the second electrode and a second portion below the first portion, the first portion extends beyond the second portion and overlaps a part of the second electrode without covering or shielding the part of the second electrode.

A display device according to embodiments of the present disclosure may reduce a size of a deposition device and a manufacturing expense, reduce complexity of the manufacturing process and improve a processing yield when performing evaporation deposition using the overhang structure layer by disposing the pixels in a stripe shape.

A display device according to embodiments of the present disclosure may form a connection configured to electrically connect a cathode electrode and the low potential driving voltage to each other in a display region in which the pixels are disposed, without increasing a process.

A display device according to embodiments of the present disclosure may improve an image quality by preventing the IR drop and allowing the low potential driving voltage to be applied uniformly between the pixels by maximizing an area of electrical connection between the cathode electrode and the low potential driving voltage.

A display device according to embodiments of the present disclosure may prevent a lateral leakage current from flowing between pixels adjacent to each other through a pattern portion formed in the bank, when the pixels are disposed in a stripe shape.

A display device according to embodiments of the present disclosure may provide a display device capable of securing an aperture ratio of a pixel and improving luminance by adjusting a width of an overhang structure layer in a stripe arrangement.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a block diagram illustrating a configuration of a display device according to an embodiment.

FIG. 2 is a circuit diagram of a pixel according to an embodiment.

FIG. 3 is a schematic plan view of a display panel having an arrangement in a dot form.

FIG. 4 is a schematic plan view of a display panel having an arrangement in a stripe form.

FIG. 5 is a cross-sectional view taken along I-I′ line illustrated in FIG. 3 or FIG. 4.

FIG. 6 is an enlarged view according to an embodiment with respect to BB region of FIG. 5.

FIG. 7 is an enlarged view according to another embodiment with respect to BB region of FIG. 5.

FIG. 8 is a schematic plan view of a display panel according to a first embodiment.

FIG. 9 is an embodiment of a cross-sectional view taken along II-II′ line in FIG. 8.

FIGS. 10A to 10E are views illustrating a method for manufacturing a display panel according to an embodiment.

FIG. 11 is a schematic plan view of a display panel according to a second embodiment.

FIG. 12 is a schematic plan view of a display panel according to a third embodiment.

FIG. 13 is a schematic plan view of a display panel according to a fourth embodiment.

FIG. 14 is an embodiment of a cross-sectional view taken along III-III′ line illustrated in FIG. 12.

FIG. 15 is another embodiment of a cross-sectional view taken along III-III′ line illustrated in FIG. 12.

FIG. 16 is a schematic plan view of a display panel according to a fifth embodiment.

FIG. 17 is a schematic plan view of a display panel according to a sixth embodiment.

### DETAILED DESCRIPTION

Hereinafter, embodiments of the disclosure will be described with reference to the drawings. In this specification, when it is mentioned that a component (or, an area, a layer, a part, etc.) is referred to as being “on”, “connected to” or “combined to” another component, this means that the component may be directly on, connected to, or combined to the other component or a third component therebetween may be present.

Like reference numerals refer to like elements. Additionally, in the drawings, the thicknesses, proportions, and dimensions of components are exaggerated for effective description. “And/or” includes all of one or more combinations defined by related components.

It will be understood that when the terms “first” and “second” are used herein to describe various components, these components should not be limited by these terms. The above terms are used only to distinguish one component from another. For example, a first component may be referred to as a second component and vice versa without departing from the scope of the present disclosure. Singular expressions and terms used herein also encompass or include plural expressions and terms, unless the context clearly indicates otherwise.

In addition, terms such as “below”, “the lower side”, “on”, and “the upper side” are used to describe a relationship of configurations shown in the drawing. The terms are described as a relative concept based on a direction shown in the drawing.

In various embodiments of the disclosure, the term “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof.

Herein, “overhang” structure may refer to, for example, a structure having a “mushroom-shape”, i.e., a structure in which the upper width is greater than the lower width thereof in a cross-sectional view. The present disclosure is not limited thereto, and “overhang” may be interpreted as a structure commonly understood by those skilled in the art.

When a first element is referred to herein as “contacting” or “overlapping” a second element, the first element may “directly contact” or “directly overlap” the second element, but the first element is not limited such scenarios, and a third element may also be inserted between the first and second elements, or the first and second elements may “contact” or “overlap” with each other via a fourth element, etc. Here, the second element may be included in at least one of the two or more elements that “contact” or “overlap” with each other, etc.

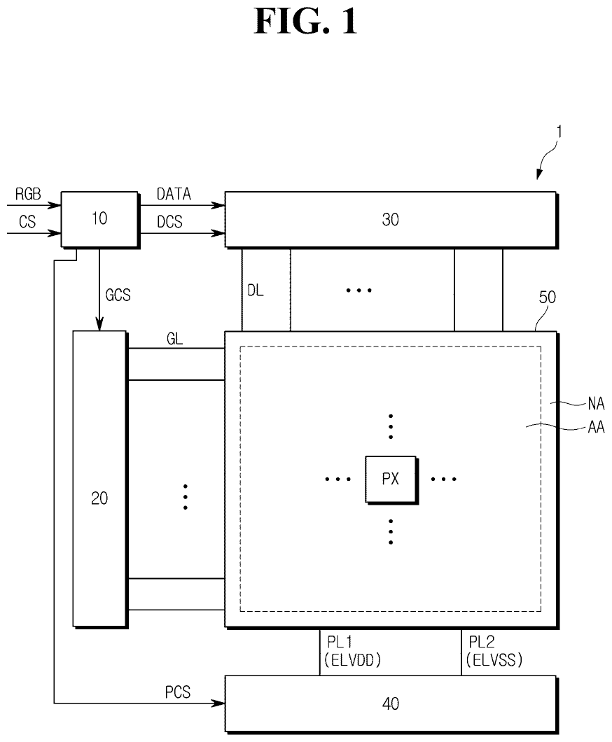

FIG. 1 is a block diagram illustrating a configuration of a display device according to an embodiment.

Referring to FIG. 1, a display device 1 may include a timing controller 10, a gate driver 20, a data driver 30, a power supply unit 40, and a display panel 50.

The timing controller 10 may be configured by being integrated to various processors, for example, a micro-processor, a mobile processor, an application processor, and the like according to devices mounted therein.

The timing controller 10 may receive a video signal RGB and a control signal CS from an external host system and the like. The video signal RGB may include a plurality of grayscale data. The control signal CS may include, for example, a horizontal synchronization signal, a vertical synchronization signal and a main clock signal.

The timing controller 10 processes the video signal RGB and the control signal CS to be suitable to operational conditions of the display panel 50, and may generate and output image data DATA, a gate driving control signal GCS, a data driving control signal DCS, and a power supply control signal PCS.

The gate driver 20 may be configured in a Gate-In-Panel form in which the gate driver 20 is mounted on the display panel 50. The gate driver 20 may be disposed on one side of the display panel 50, or on both sides (for example, left and right sides) of the display panel 50. FIG. 1 schematically illustrates a case where the gate driver is provided on one side (e.g., left side) of the display panel. The gate driver can also be provided on the right side of the display panel. In addition, according to a driving method, a panel design manner, and the like, the gate driver 20 may be disposed on both sides (for example, left and right sides) of the display panel 50, or may be connected to two or more side surfaces among four side surfaces of the display panel 50. The gate driver may also be configured in other appropriate forms.

The gate driver 20 may generate scan signals based on the gate driving control signal GCS output from the timing controller 10. The gate driver 20 may provide the generated scan signals to the pixels PX through a plurality of gate lines GL.

In an embodiment, one pixel PX may be configured to receive a plurality of scan signals having different waveforms. In such an embodiment, the gate driver 20 may provide the plurality of scan signals to the pixels PX through the gate lines GL corresponding thereto, respectively.

The data driver 30 may generate data signals based on the data driving control signal DCS and image data DATA output from the timing controller 10. The data driver 30 may provide the generated data signals to the pixels PX through a plurality of data lines DL.

The power supply unit 40 may generate a high potential driving voltage ELVDD and a low potential driving voltage ELVSS to be provided to the display panel 50 based on the power supply control signal PCS. The power supply unit 40 may provide the generated high potential driving voltage ELVDD and low potential driving voltage ELVSS to the pixels PX through corresponding voltage lines PL1 and PL2. As shown in FIG. 1, the generated high potential driving voltage ELVDD can be provided to the pixels PX through voltage line PL1, and such voltage line PL1 may be referred to as a high potential driving voltage line; and the generated low potential driving voltage ELVSS can be provided to the pixels PX through voltage line PL2, and such voltage line PL2 may be referred to as a low potential driving voltage line. The present disclosure is not limited thereto, and may include other suitable voltage line configurations. In addition, the power supply unit 40 may further generate a reference voltage and the like required for driving the pixel PX, and provide it to the pixels PX through a corresponding voltage line. The reference voltage may be provided through other voltage line than the voltage lines PL1 and PL2 as shown in FIG. 1.

The display panel 50 may be implemented as a transmissive or a non-transmissive display panel. The transmissive display panel may be applied to a transparent display device of which an image is displayed in the screen and a real background object is visible.

The display panel 50 may be manufactured as a flexible display panel. The flexible display panel may be implemented as an OLED panel which uses a plastic substrate.

The display panel 50 may include a display region AA and a non-display region NA around the display region AA. In an embodiment, the non-display region NA may be formed to surround the display region AA, and may correspond to a bezel region, but is not limited thereto.

On the display panel 50, a plurality of pixels PX (or referred to as sub-pixels) is disposed. The pixels PX may be disposed, for example, in a matrix form in the display region AA. The pixels disposed in one pixel row are connected to the same gate line GL, and the pixels PX disposed in one pixel column are connected to the same data line DL. The pixels PX may emit light at luminance corresponding to a scan signal supplied through the gate line GL and a data signal supplied through the data line DL.

Each pixel PX may include the light emitting element and a driving circuit configured to drive the light emitting element. The light emitting element included in the pixel PX may display one color among red, green and blue.

In another embodiment, the light emitting element may display one color among cyan, magenta and yellow. In various embodiments, the light emitting element may display one color among red, green, blue and white.

In an embodiment, touch sensors may be further disposed on the display panel 50. A touch input may be sensed using additional touch sensors or may be sensed through pixels PX. The touch sensors may be disposed on the display panel 50 in an on-cell type or an add-on type, or may be implemented as in-cell type touch sensors embedded to the display panel 50.

The timing controller 10, the gate driver 20, the data driver 30 and the power supply unit may be configured as separate Integrated Circuits (IC) or at least some parts thereof together may be integrated into and form the Integrated Circuit.

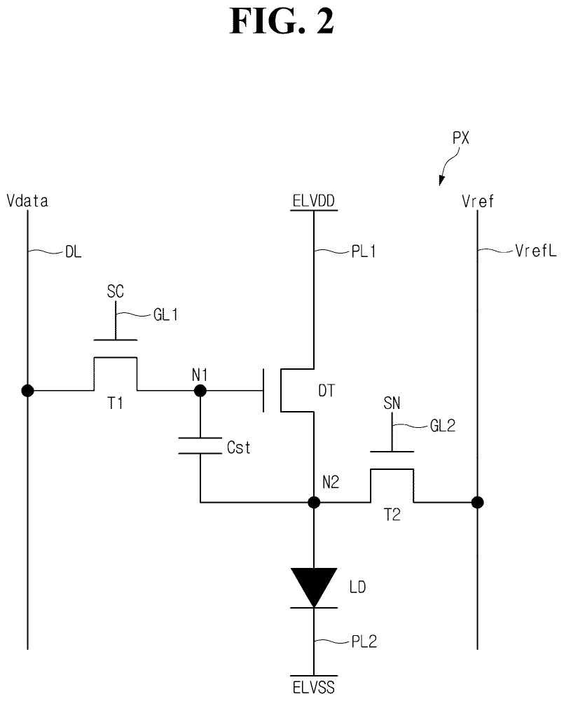

FIG. 2 is a circuit diagram of the pixel according to an embodiment.

Referring to FIG. 2, the pixel PX according to an embodiment may include a driving transistor DT, a light emitting element LD connected to the driving transistor DT, and a control circuit configured to control an amount of a driving current to be applied to the light emitting element LD through the driving transistor DT. For example, the control circuit may include transistors T1 and T2, and a storage capacitor Cst.

A first electrode of the driving transistor DT is configured to receive a high potential driving voltage ELVDD (connected to a high potential driving voltage line PL1), and a second electrode thereof is connected to the light emitting element LD through a second node N2. A gate electrode of the driving transistor DT is connected to the data line DL through a first node N1. The driving transistor DT may be turned on according to a voltage difference between the first node N1 and the second node N2 (that is, a gate-source voltage) and may control an amount of the driving current flowing to the light emitting element LD.

The first electrode of the first transistor T1 is connected to the data line DL, and the second electrode thereof is connected to the gate electrode of the driving transistor DT through the first node N1. A gate electrode of the first transistor T1 may be connected to a first gate line GL1 and may receive a first gate signal. The first gate signal is a scan signal SC, and may be a control signal applied so as to program a data voltage Vdata into the pixel PX.

The first transistor T1 may be turned on according to the scan signal SC applied to the first gate line GL1, and may transfer a data voltage Vdata applied to the data line DL to the first node N1. Such a first transistor T1 may be referred to as a switching transistor.

A first electrode of the second transistor T2 is connected to a reference voltage line VrefL, and a second electrode thereof is connected to the second node N2. A gate electrode of the second transistor T2 may be connected to a second gate line GL2 and may receive a second gate signal. A second gate signal is a sensing signal SN, and may be a control signal applied so as to apply a reference voltage to the pixel PX, or sense an electric characteristic of the pixel PX.

The second transistor T2 may be turned on according to the sensing signal SN applied to the second gate line GL2, and may electrically connect the reference voltage line VrefL and the second node N2 to each other. When the reference voltage Vref is applied to the reference voltage line VrefL, the reference voltage Vref may be applied to the second node N2 through the second transistor T2 turned on.

When the reference voltage line VrefL is not connected to the reference voltage Vref, a sensing signal (for example, a current, a voltage) applied to the second node N2 may flow through the reference voltage line VrefL to be transferred to the data driver 30 (FIG. 1) and/or the timing controller 10 (FIG. 1) etc. The transferred sensing signal may be used to sense an electric characteristic of the pixel PX. Such a second transistor T2 may be referred to as an initialization transistor and/or a sensing transistor.

The storage capacitor Cst is connected between the first node N1 and the second node N2. The storage capacitor Cst may store a voltage corresponding to a voltage difference between the first node N1 and the second node N2, and maintain the stored voltage during one frame period, thereby stabilizing a voltage of the gate electrode (that is, the first node N1) of the driving transistor DT.

The anode electrode of the light emitting element LD may be connected to the driving transistor DT through the second node N2, and the cathode electrode thereof may be connected to the low potential driving voltage ELVSS (connected to the low potential driving voltage line PL2). When the driving transistor DT is turned on, a current path is formed between the high potential driving voltage ELVDD and the low potential driving voltage ELVSS, and a driving current may flow to the light emitting element LD. The light emitting element LD may emit light at luminance corresponding to an amount of the driving current applied thereto.

In the embodiment illustrated in FIG. 2, the pixel PX may include an oxide semiconductor transistor. The oxide semiconductor transistor includes a gate electrode, a source electrode, and a drain electrode. The oxide semiconductor transistor has an active layer formed of an oxide semiconductor.

Here, the oxide semiconductor may be set as an amorphous oxide semiconductor or a crystalline oxide semiconductor. The oxide semiconductor transistor may be configured as an n-type transistor. The oxide semiconductor transistor may be formed through a low temperature process and has a lower charge mobility than that of the LTPS (Low Temperature Poly-Silicon) transistor. Such an oxide semiconductor transistor has an excellent off current characteristic.

In another embodiment, the pixel PX may be a hybrid type further including the LTPS (Low Temperature Poly-Silicon) transistor.

The LTPS transistor includes a gate electrode, a source electrode, and a drain electrode. The LTPS transistor has an active layer formed of poly silicon. The LTPS transistor includes an active layer formed of poly silicon. Such an LTPS transistor may be configured as a P-type transistor or an N-type transistor. The LTPS transistor has a high electron mobility, and therefore, has a fast driving characteristic.

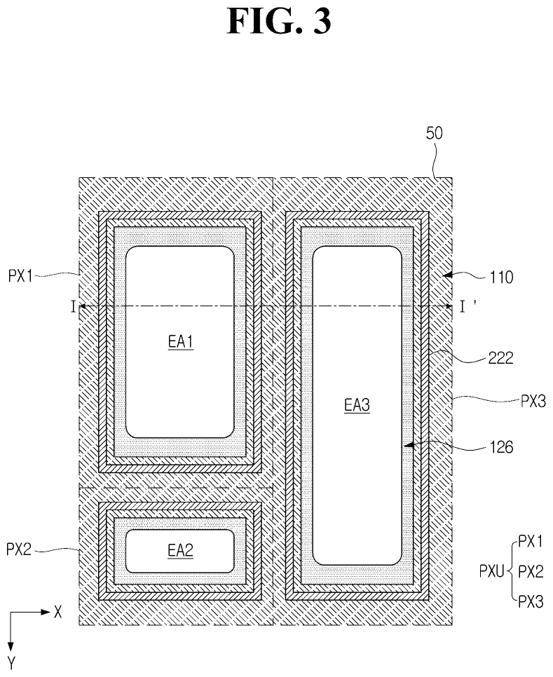

FIG. 3 is a schematic plan view of the display panel having an arrangement in a dot form. In FIG. 3, one portion of the display region AA (FIG. 1) in which the pixels PX1, PX2 and PX3 are disposed is illustrated.

Referring to FIG. 3, the display panel 50 according to an embodiment includes a plurality of unit pixels PXU. Each of the unit pixels PXU includes a plurality of pixels PX1, PX2, and PX3 configured to emit a color different from one another. In an embodiment, each of the plurality of pixels PX1, PX2 and PX3 may display one color among red, green, and blue. However, the embodiment is not limited thereto. The unit pixels may further include pixels other than the plurality of pixels PX1, PX2, and PX3. In such unit pixels, one or more pixels displaying white color may also be included, in addition to the plurality of pixels PX1, PX2, and PX3 each displaying one color among red, green, and blue. In another embodiment, the plurality of pixels PX1, PX2, and PX3 may each display one color among cyan, magenta, and yellow.

In an embodiment, the first pixel PX1 and the third pixel PX3 may be disposed alternately along a first direction X. In addition, the second pixel PX2 and the third pixel PX3 may be disposed alternately along the first direction X. The first direction may be a horizontal direction. However the embodiment is not limited thereto, e.g., the first direction may also be a vertical direction.

The first pixel PX1 and the second pixel PX2 may be alternately disposed along a second direction Y generally perpendicular to the first direction X. The third pixel PX3 may be disposed along the second direction Y. That is, the display panel 50 may include a first pixel column in which the first pixel PX1 and the second pixel PX2 are alternately disposed and a second pixel column in which the third pixel PX3 is disposed. An order of the first pixel column and the second pixel column in the unit pixel PXU may be changed from what is illustrated in the drawing. In addition to the configuration as shown in FIG. 3, other suitable configurations of the first and second pixel columns may be included. For example, the third pixel PX3 may be disposed in the first pixel column, and the first pixel PX1 and the second pixel PX2 may be alternately disposed in the second pixel column. The second direction may be a vertical direction. However, the embodiment is not limited thereto, e.g., the second direction may also be a horizontal direction.

The first pixel PX1, the second pixel PX2 and the third pixel PX3 may be surrounded by an overhang structure layer 110 which defines regions (hereinafter, pixel regions) of the pixels PX1, PX2 and PX3. An exposed region not covered by the overhang structure layer 110 may be defined as the pixel region of each of the pixels. According to some embodiments of an aspect, the overhang structure layer 110 comprises a lower layer with a smaller width and an upper layer with a larger width, the lower layer does not cover the pixel region, and the upper layer can cover a part of the pixel regions, for example, cover the boundary portions of the pixel regions.

Each of the pixels PX1, PX2 and PX3 may include an emission region EA1, EA2 and EA3 in correspondence therewith. Each of the emission regions EA1, EA2 and EA3 may be a region in which an anode electrode, an emission layer and a cathode electrode of the light emitting element LD (FIG. 2) are in contact with each other and stacked.

Each of the emission regions EA1, EA2 and EA3 may be surrounded by a bank 126 which defines the emission regions EA1, EA2 and EA3. For example, the bank 126 may be formed on the anode electrode, and may include an opening exposing one region of the anode electrode. One region of the anode electrode not covered by the bank 126 and exposed may be defined as the emission regions EA1, EA2 and EA3.

In an embodiment, the emission regions EA1, EA2 and EA3 may be smaller than the defined pixel region, but the embodiment is not limited thereto. In another embodiment, the emission regions EA1, EA2 and EA3 may be defined to have the same size and same shape as those of the pixel region.

In an embodiment, a first cathode connection 222 may be provided to overlap the overhang structure layer 110. The first cathode connection 222 may be provided to electrically connect the cathode electrode and an auxiliary cathode electrode of the light emitting element LD.

Detailed structures of the overhang structure layer 110 and the first cathode connection 222 will be described with reference to the drawing below.

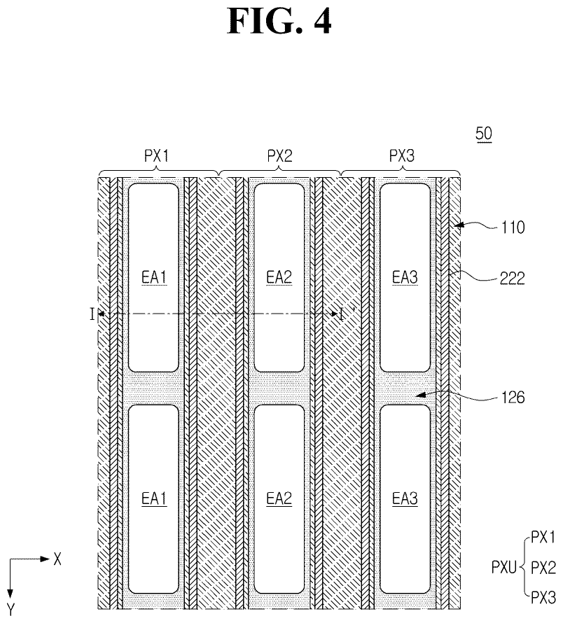

FIG. 4 is a schematic plan view of the display panel having an arrangement in a stripe form.

In FIG. 4, a portion of the display region AA (FIG. 1) in which the pixels PX1, PX2 and PX3 are disposed is illustrated.

Referring to FIG. 4, the display panel 50 according to an embodiment may include a plurality of unit pixels PXU. Each of the unit pixel PXU may include a plurality of pixels PX1, PX2 and PX3 configured to emit colors different from one another. In an embodiment, the plurality of pixels PX1, PX2 and PX3 may display one color among red, green and blue. However, the embodiment is not limited thereto. The unit pixels may further include pixels other than the plurality of pixels PX1, PX2, and PX3. In such unit pixels, one or more pixels displaying white color may also be included, in addition to the plurality of pixels PX1, PX2, and PX3 each displaying one color among red, green, and blue. In another embodiment, the plurality of pixels PX1, PX2, and PX3 may each display one color among cyan, magenta, and yellow.

In an embodiment, the pixels PX1, PX2 and PX3 forming one unit pixel PXU and configured to emit colors different from one another may be sequentially and alternately disposed along the first direction X. The first direction may be a horizontal direction. However the embodiment is not limited thereto, e.g., the first direction may also be a vertical direction. In addition, the pixels PX1, PX2 and PX3 configured to emit the same color may be disposed along the second direction Y generally perpendicular to the first direction. The second direction may be a vertical direction. However, the embodiment is not limited thereto, e.g., the second direction may also be a horizontal direction.

Each of the pixels PX1, PX2 and PX3 may be in contact with the overhang structure layer 110 configured to define regions (hereinafter, pixel regions) of the pixels PX1, PX2 and PX3. For example, each of the pixels PX1, PX2 and PX3 may be in contact with the overhang structure layer 110 in the first direction X. In another embodiment, each of the pixels PX1, PX2 and PX3 may be in contact with the overhang structure layer 110 in the second direction Y.

Like FIG. 3, each of the pixels PX1, PX2 and PX3 may include the emission region EA1, EA2 and EA3 in correspondence therewith. Each of the emission regions EA1, EA2 and EA3 may be surrounded by the bank 126 which defines the emission regions EA1, EA2 and EA3. FIG. 4 schematically illustrates that the pixels PX1, PX2, and PX3 each include two emission regions separated from each other. For example, the pixel PX1 includes two emission regions EA1 separated from each other, the pixel PX2 includes two emission regions EA2 separated from each other, and the pixel PX3 includes two emission regions EA3 separated from each other. However, the embodiment is not limited thereto; the pixels PX1, PX2, and PX3 may each include more emission regions separated from each other.

In addition, the first cathode connection 222 may be provided in the overhang structure layer 110. In an embodiment, the first cathode connection 222 may be covered by the overhang structure layer 110 and overlap the overhang structure layer 110 on a plane. In an embodiment of an aspect, the first cathode connection 222 may be provided to correspond to the lower layer 110A of the overhang structure layer 110. In an embodiment, in a plan view, the first cathode connection 222 may be configured to extend beyond the lower layer 110A of the overhang structure layer 110; or may extend as not beyond the lower layer 110A of the overhang structure layer 110 so as to be completely overlapped by the overhang structure layer 110. In an embodiment, the first cathode connection 222 may be disposed in the overhang structure layer 110 or formed as a part of the overhang structure layer 110.

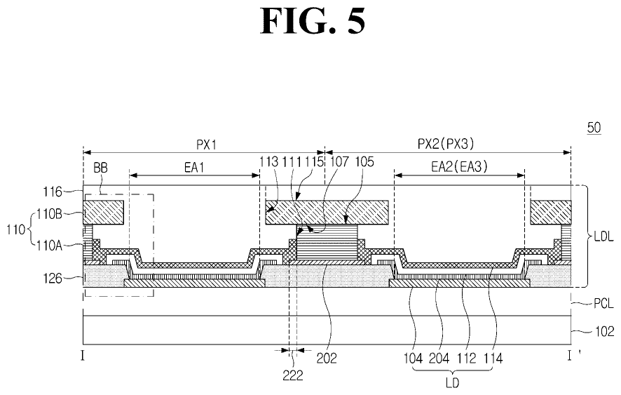

FIG. 5 is a cross-sectional view taken along I-I′ line illustrated in FIG. 3 or FIG. 4.

Referring to FIG. 5, the display panel 50 according to an embodiment may include a substrate 102 and pixels PX1 and PX2 (PX3) disposed on the substrate 102.

The substrate 102 supports various components of the display panel 50. The substrate 102 may be formed of a transparent insulating material, for example, glass, plastic, and the like. When the substrate 102 is formed of plastic, it may be referred to as a plastic film or a plastic substrate.

For example, the substrate 102 may be in a film form which includes one among polyimide polymer, polyester polymer, silicon polymer, acrylic polymer, polyolefin polymer, and a copolymer thereof, but the embodiments of the present disclosure are not limited thereto. The substrate 102 may include one, two or more layers of a film formed by the above polymers. Also, when the substrate 102 is formed of plastic, the substrate 102 may be formed in a dual structure. For example, the substrate 102 may have a dual structure having an adhesive layer between a first polyimide layer and a second polyimide layer. For example, the substrate 102 may have a structure which includes an inter-layer insulating layer formed of an inorganic insulating material and interposed between the first polyimide layer and the second polyimide layer.

When the substrate 102 is formed of glass, the substrate 102 may be referred to as a glass substrate. For example, the glass substrate may further include a shielding metal (not illustrated), and may serve to protect the device from external light or signal interference.

A circuit element layer PCL may be disposed on the substrate 102. On the circuit element layer PCL, circuit elements such as at least one transistors DT, T1 and T2 and a capacitor Cst described with reference to FIG. 2 may be disposed. For example, the circuit element layer PCL may include a semiconductor pattern forming a circuit element, conductive electrodes, and at least one insulating layer electrically insulating therebetween. In addition, the circuit element layer PCL may further include at least one protection layer for protecting the circuit elements from external invasion and/or at least one planarization layer for planarizing an upper surface of the circuit element layer PCL. A configuration and a structure of the circuit element layer PCL in detail are not specifically limited.

An emission element layer LDL on which the light emitting elements LD are disposed may be disposed on the circuit element layer PCL.

In more detail, a first electrode 104 may be patterned on the circuit element layer PCL. The first electrode 104 may be, for example, an anode electrode 104. In another embodiment, the first electrode may be, for example, a cathode electrode, and may apply to the following descriptions on cathode electrode.

The anode electrode 104 may be formed of a metal material such as chromium, titanium, gold, silver, copper, aluminum and the like. Alternatively, the anode electrode 104 may include a metal material having a high reflectance such as a stacked structure of aluminum (Al) and titanium (Ti)(Ti/Al/Ti), a stacked structure of aluminum (Al) and indium tin oxide (ITO)(ITO/Al/ITO), and an APC alloy. The anode electrode 104 may consist of a single layer or multiple layers, but the embodiments of the present disclosure are not limited thereto.

Such an anode electrode 104 may be patterned in correspondence with each of the pixels PX1 and PX2 (PX3). In addition, the anode electrode 104 may be electrically connected to a transistor (for example, the driving transistor DT) of each pixel PX1 and PX2 (PX3) disposed on the circuit element layer PCL through a contact hole and the like.

The bank 126 may be formed on the anode electrode 104. The bank 126 may include an opening overlapping the anode electrode 104. The opening may correspond to, for example, a center region of the anode electrode 104. In such an embodiment, the bank 126 may cover one region of the anode electrode 104, for example, an edge, and expose the remaining other region, for example, a center region, upward through the opening.

The bank 126 may be formed widely on the substrate 102. The exposed region of the anode electrode 104 not covered by the bank 126 may be defined as an emission region. An emission layer 112 and a cathode electrode 114, which will be described below, may be sequentially stacked and in direct contact with each other in the exposed region of the anode electrode 104, thereby forming the light emitting element LD.

The bank 126 may be formed of an opaque material so as to prevent light interreference between the pixels adjacent to each other. For example, the bank 126 may be formed of an organic material such as a benzocyclobutene resin, a polyimide resin, an acrylic resin, or photosensitive polymer.

Alternatively, the bank 126 may include a black-based material, and may include a light shielding material formed of at least one among, for example, a color pigment (a black pigment), a black dye, organic black, and carbon (black bank). When the bank 126 is formed of the black-based material, the bank 126 may shield external light, and thus, may further improve luminance of the display panel 50. At this instance, the bank 126 may serve to absorb light reflected from a lower side (e.g. the side facing the substrate 102) of the bank 126 among light incident from the outside.

In an embodiment, the bank 126 may be in a multi-layer structure. For example, the bank 126 may include one among an organic layer, and an organic layer having an inorganic coating or an inorganic layer disposed on the organic layer. The inorganic layer may include, for example, silicon oxide SiO₂, silicon nitride Si₃N₄, silicon oxynitride SiON, magnesium fluoride MgF₂, or combinations thereof. In addition, in an embodiment in which the bank 126 is formed in a multi-layer structure, a portion of the multi-layer (for example, a lower layer) of the bank 126 may include a black-based material, and a remaining other (for example, an upper layer) may include a transparent material.

The overhang structure layer 110 may be disposed on the bank 126. The overhang structure layer 110 may be formed to define a region of each of the pixels PX1 and PX2.

In an embodiment, the overhang structure layer 110 may include a lower layer 110A disposed adjacent to the bank 126, and an upper layer 110B disposed on the lower layer 110A. The lower layer 110A and the upper layer 110B may be formed of a non-conductive inorganic material or a conductive inorganic material. In an embodiment, the lower layer 110A may be formed of a conductive inorganic material, and the upper layer 110B may be formed of a non-conductive inorganic material. In another embodiment, the lower layer 110A may be formed of a non-conductive inorganic material, and the upper layer 110B may be formed of a conductive inorganic material. In still another embodiment, both the lower layer 110A and the upper layer 110B may be formed of a conductive inorganic material. In still another embodiment, both the lower layer 110A and the upper layer 110B may be formed of a non-conductive inorganic material.

In an embodiment in which the lower layer 110A is formed of a non-conductive inorganic material, an auxiliary cathode electrode 202 may be further formed below the overhang structure layer 110. Hereinafter, an example in which the lower layer 110A is formed of a non-conductive inorganic material, and the auxiliary cathode electrode 202 is formed below the overhang structure layer 110 is assumed.

In another embodiment, the lower layer 110A is formed of a conductive inorganic material, and the auxiliary cathode electrode 202 may be further formed. In such an embodiment, the lower layer 110A and the auxiliary cathode electrode 202 may be one structure. In such embodiment, the lower layer 110A and the auxiliary cathode electrode 202 can be integrally formed through the same process.

The non-conductive inorganic material may include, for example, an inorganic silicon-containing material. For example, the silicon-containing material may include, for example, oxides or nitrides of silicon, or combinations thereof, but is not limited thereto. The conductive inorganic material may include a metal-containing material. For example, the metal-containing material includes copper, titanium, aluminum, molybdenum, silver, indium tin oxide, indium zinc oxide, or combinations thereof. However, the material of the overhang structure layer 110 is not limited thereto.

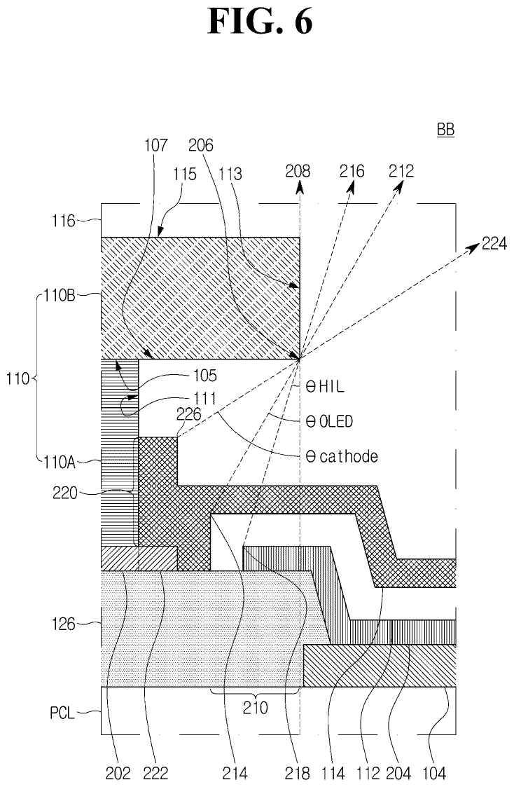

In an embodiment, in order to form an overhang, a lower surface 107 of the upper layer 110B of the overhang structure layer 110 may be formed wider than an upper surface 105 of the lower layer 110A. As shown in FIG. 5, in the horizontal direction, the left side surface (side surface 113) of the upper layer 110B of the overhang structure layer 110 may be located further to the left side (outer side) than the left side surface (side surface 111) of the lower layer 110A of the overhang structure layer 110; the right side surface of the upper layer 110B of the overhang structure layer 110 may be located further to the right side (outer side) than the right side surface of the lower layer 110A of the overhang structure layer 110, thereby forming an overhang structure in which the upper layer 110B of the overhang structure layer 110 protrudes outward on both sides relative to the lower layer 110A. With this structure, a shadowing effect may be supported during the evaporation deposition of the emission layer 112 and the cathode electrode 114. That is, evaporation sources of the emission layer 112 and the cathode electrode 114 may be deposited on the lower layer along a predetermined incident angle through the overhang structure layer 110. Such a shadowing effect of the overhang structure layer 110 may be described in detail referring to FIG. 6 below.

The emission layer 112 may be formed on the anode electrode 104. In an embodiment, the emission layer 112 may be formed in at least one region of the bank 126 and a region of the anode electrode 104 which is not covered by the bank 126 and exposed.

The emission layer 112 may be formed of an organic material which emits light in correspondence with a voltage applied to the anode electrode 104 and the cathode electrode 114 which will be described below. In an embodiment, the emission layer 112 may emit light in one color among red, green, and blue according to kinds of an organic material. However, the embodiment is not limited thereto, and the emission layer 112 may be configured to emit light in a different color such as white and the like. The emission layer 112 may also be configured to emit light in one color among cyan, magenta, and yellow.

In an embodiment, a common layer 204 may be interposed between the anode electrode 104 and the emission layer 112. The common layer 204 is an organic layer, and for example, may include a hole transport layer HTL, a hole injection layer HIL, an electron transport layer ETL, and/or an electron injection layer EIL, but is not limited thereto.

A second electrode 114 may be formed on the emission layer 112. The second electrode 114 may be the cathode electrode 114. The cathode electrode 114 may be formed of a conductive material, for example, a metal. For example, the cathode electrode 114 may be formed of silver, magnesium, chromium, titanium, aluminum or a combination thereof, but is not limited thereto. In another embodiment, the second electrode may be, for example, an anode electrode, and can apply to the above description on anode electrode.

The cathode electrode 114 may be formed on the emission layer 112 and one region of the bank 126 which is not covered by the emission layer 112. In an embodiment, the cathode electrode 114 may be further formed on one portion of a side wall of the lower layer 110A of the overhang structure layer 110.

Meanwhile, the auxiliary cathode electrode 202 may be further formed on the bank 126. The auxiliary cathode electrode 202 may be formed of the same material as the cathode electrode 114. For example, the auxiliary cathode electrode 202 may be formed of silver, magnesium, chromium, titanium, aluminum or a combination thereof, but is not limited thereto. The auxiliary cathode electrode 202 may be formed through the same process as the cathode electrode 114.

The auxiliary cathode electrode 202 may be interposed between the bank 126 and the overhang structure layer 110, and at least one region 222 (a cathode connection) thereof may be formed to protrude outward of the lower layer 110A of the overhang structure layer 110.

In an embodiment, at least one region of the cathode electrode 114 may be in contact with the auxiliary cathode electrode 202. That is, the cathode electrode 114 may be in contact with the auxiliary cathode electrode 202 in a region 222 in which the auxiliary cathode electrode 202 protrudes outward of the lower layer 110A. In such an embodiment, the lower layer 110A of the overhang structure layer 110 may be formed of a non-conductive inorganic material. In addition, in such an embodiment, the cathode electrode 114 may be formed to cover a side surface of the emission layer 112, and the emission layer 112 may be formed not to be in contact with the auxiliary cathode electrode 202.

In a structure in which the auxiliary cathode electrode 202 is omitted, the cathode electrode 114 may be in contact with the lower layer 110A of the overhang structure layer 110. In such an embodiment, the lower layer 110A may be formed of a conductive inorganic material. In addition, in such an embodiment, the cathode electrode 114 may be formed to cover a side surface of the emission layer 112, and the emission layer 112 may be formed not to be in contact with the lower layer 110A of the overhang structure layer 110.

In an embodiment, the cathode electrode 114 may be electrically connected to the low potential driving voltage line PL2 (FIG. 2) formed on the substrate 102. For example, the cathode electrode 114 may be electrically connected to the low potential driving voltage line PL2 through the lower layer 110A of the overhang structure layer 110 formed of a conductive inorganic material, or the auxiliary cathode electrode 202. In an embodiment in which the lower layer 110A of the overhang structure layer 110 is formed of a conductive inorganic material, and the auxiliary cathode electrode 202 is omitted, the cathode electrode 114 may be connected to the low potential driving voltage line PL2 through a bus bar disposed outside the region of the pixel PX1 and PX2 (PX3).

In an embodiment which is not illustrated, the emission layer 112, and the cathode electrode 114 may be further formed on the upper layer 110B of the overhang structure layer 110. For example, the emission layer 112, and the cathode electrode 114 may be further formed on at least one portion of a side surface 113 and at least one portion of an upper surface 115 of the upper layer 110B. However, the embodiment is not limited thereto.

An encapsulation layer 116 may be formed on the cathode electrode 114. The encapsulation layer 116 may be a local passivation layer disposed in the region of each pixel PX1 and PX2, or a layer in correspondence therewith. The encapsulation layer 116 may block moisture or oxygen from the outside from invading into the light emitting element LD. The encapsulation layer 116 may be formed of a non-conductive inorganic material such as silicon nitride SiN_{X}, silicon oxide SiOₓ, silicon oxynitride SiON or aluminum oxide Al₂O₃, but is not limited thereto.

The encapsulation layer 116 may cover the cathode electrode 114, and extend along a side wall and an upper surface and a lower surface of the overhang structure layer 110. For example, the encapsulation layer 116 may be disposed to cover a side surface 111 of the lower layer 110A of the overhang structure layer 110. In addition, the encapsulation layer 116 may be disposed to cover a side surface 113, an upper surface 115 and at least a part of a lower surface 107 of the upper layer 110B of the overhang structure layer 110.

In an embodiment, one or more capping layers may be disposed between the cathode electrode 114 and the encapsulation layer 116. The capping layer may be in a single-layer structure, or a multi-layer structure. The capping layer may be formed of at least one material selected from an organic material and an inorganic material. In the embodiments where the capping layer includes a multi-layer structure, such as a double-layer structure, for example, a lower capping layer may be formed of an organic material, and an upper capping layer may be formed of an inorganic material, but not limited thereto.

In addition, in an embodiment, a passivation layer may be further provided on the encapsulation layer 116. The passivation layer may be a global passivation layer formed to cover the entire pixels PX1 and PX2. The passivation layer may planarize a step difference formed by the lower layer and may protect components disposed on a lower side. The passivation layer may be in a single-layer structure, or a multi-layer structure.

In an embodiment, an inkjet layer, a photoresist, a color filter, or a photosensitive monomer and the like may be further disposed between the encapsulation layer 116 and the passivation layer, but the embodiment is not limited thereto.

FIG. 6 is an enlarged view according to an embodiment with respect to BB region of FIG. 5. In more detail, FIG. 6 shows a schematic cross-section of the overhang structure layer 110.

In FIG. 6, an embodiment in which the lower layer 110A of the overhang structure layer 110 is formed of a non-conductive inorganic material, and the auxiliary cathode electrode 202 is provided is illustrated representatively. However, the embodiments below may be applied to an embodiment in which the lower layer 110A is formed of a conductive inorganic material, and the auxiliary cathode electrode 202 is omitted.

Referring to FIG. 6, the emission layer 112 may be formed on the bank 126. In addition, the auxiliary cathode electrode 202 may be further formed on the bank 126.

On the auxiliary cathode electrode 202, the overhang structure layer 110 may be formed. The overhang structure layer 110 may include the lower layer 110A and the upper layer 110B.

The lower layer 110A may be formed on the auxiliary cathode electrode 202. At this instance, one region 222 of the auxiliary cathode electrode 202 may be formed such that the one region 222 is not covered by the lower layer 110A and exposed to an outside. As shown in FIG. 6, the one region 222 of the auxiliary cathode electrode 202 may be formed as a step. That is, the upper surface of the auxiliary cathode electrode 202 may be higher than the upper surface of the bank 126, and the side surface of the auxiliary cathode electrode 202 may be located further outward relative to the side surface 111 of the lower layer 110A of the overhang structure layer 110 and protrude from the side surface 111 of the lower layer 110A of the overhang structure layer 110, thereby forming a step.

A lower surface 107 of the upper layer 110B may be formed wider than an upper surface 105 of the lower layer 110A so that an overhang is formed. In other words, the overhang structure layer 110 may have a side surface in an inverse taper form. Such an overhang structure layer 110 may be formed by depositing a construction material of the lower layer 110A and the upper layer 110B and patterning them in an inverse taper form. Alternatively, the overhang structure layer 110 may be formed by patterning the lower layer 110A and patterning the upper layer 110B on the patterned lower layer 110A again.

In such an embodiment, a lower edge 206 of the upper layer 110B may be formed on an outside (toward the emission region) of the lower layer 110A. At this instance, an overhang vector 208 passing through the lower edge 206 of the upper layer 110B and extending perpendicularly (perpendicular to the lower surface 107 of the upper layer 100B) may be defined. By this overhang structure, the layers on a lower side may not be covered by the lower layer 110A, and may have a shadow region 210 overlapping (shadowed) the upper layer 110B on the plane.

The emission layer 112 may be formed on the common layer 204 and one region of the bank 126. A side surface of the emission layer 112 may be formed not to be in contact with the lower layer 110A of the overhang structure layer 110 and the auxiliary cathode electrode 202.

In more detail, the emission layer 112 may be formed on the anode electrode 104 and the shadow region 210 of the bank 126. As shown in FIG. 6, the emission layer 112 overlaps the upper layer 110B of the overhang structure layer 110. In the horizontal direction, the edge 214 of the emission layer 112 is located at the left side of the lower edge 206 of the upper layer 110B of the overhang structure layer 110. In the vertical direction, the upper layer 110B of the overhang structure layer 110 shadows the edge 214 of the emission layer 112 from above. That is, an edge 214 of the emission layer 112 may be formed below the upper layer 110B. At this instance, an emission layer vector 212 extending toward the lower edge 206 of the upper layer 110B from the edge 214 of the emission layer 112 may be defined. The emission layer 112 may be formed to have a predetermined emission layer angle θOLED defined between the emission layer vector 212 and the overhang vector 208. The emission layer angle θOLED may be between 0° to 90°, but not limited thereto.

In an embodiment, the common layer 204 may be formed between the bank 126 and the emission layer 112. The common layer 204 may be disposed on the anode electrode 104 and the shadow region 210 of the bank 126. That is, an edge 218 of the common layer 204 may be formed below the upper layer 110B. As shown in FIG. 6, the common layer 204 overlaps the upper layer 110B of the overhang structure layer 110. In the horizontal direction, the edge 218 of the common layer 204 is located at the left side of the lower edge 206 of the upper layer 110B of the overhang structure layer 110. In the vertical direction, the upper layer 110B of the overhang structure layer 110 shadows the edge 218 of the common layer 204 from above. At this instance, a common layer vector 216 extending toward the lower edge 206 of the upper layer 110B from the edge 218 of the common layer 204 may be defined. The common layer 204 may be formed to have a predetermined common layer angle θHIL defined between the common layer vector 216 and the overhang vector 208. The common layer angle θHIL may be between 0° to 90°, but not limited thereto.

The cathode electrode 114 may be formed on the emission layer 112 and one region of the bank 126. In addition, the cathode electrode 114 may be further formed to be in contact with the lower layer 110A of the overhang structure layer 110 and the auxiliary cathode electrode 202. For example, the cathode electrode 114 may be formed in one region 220 of the side surface 111 of the lower layer 110A, and formed to be in contact with a protruding region 222 (the cathode connection) of the auxiliary cathode electrode 202.

An edge 226 of the cathode electrode 114 may be formed on the side surface 111 of the lower layer 110A. At this instance, a cathode vector 224 extending toward the lower edge 206 of the upper layer 110B from the edge 226 of the cathode electrode 114 may be defined. The cathode electrode 114 may be formed to have a predetermined cathode angle θcathode defined between the cathode vector 224 and the overhang vector 208. The cathode angle θcathode may be between 0° to 90°, but not limited thereto.

The encapsulation layer 116 may be formed on the cathode electrode 114. In addition, the encapsulation layer 116 may be formed along an exposed outer wall (for example, the upper surface 115, side surface 113, and lower surface 107 of the upper layer 110B of the overhang structure layer 110, and the side surface 111 of the lower layer 110A of the overhang structure layer 110) of the overhang structure layer 110.

In such a structure described above, during evaporation deposition of the emission layer 112, the common layer 204 and the cathode electrode 114, the lower edge 206 of the upper layer 110B may determine a position of the edge 214 of the emission layer 112. For example, the emission layer 112 may be vapor-deposited at the greatest angle in correspondence with the emission layer vector 212, and the lower edge 206 may prevent the emission layer 112 from being deposited across the edge 214 of the emission layer 112. In embodiments having the common layer 204, the common layer 204 is vapor-deposited at the greatest angle in correspondence with the common layer vector 216, and the lower edge 206 prevents the common layer 204 from being deposited across the edge 218 of the common layer 204. The cathode electrode 114 may be vapor-deposited at the greatest angle in correspondence with the cathode vector 224, and the lower edge 206 may prevent the cathode electrode 114 from being deposited across the edge 226 of the cathode electrode 114.

In an embodiment, the emission layer angle θOLED may be smaller than a cathode angle θcathode. In addition, the common layer angle θHIL may be smaller than the emission layer angle θOLED. By providing the relationship between the emission layer angle θOLED and the cathode angle θcathode, as well as the relationship between the common layer angle θHIL and the emission layer angle θOLED in such manner, the cathode 114 may be formed as covering the upper and side surfaces of the emission layer 112, and the emission layer 112 may be formed as covering the upper and side surfaces of the common layer 204.

In addition, by providing an appropriate cathode angle θcathode, e.g., making the cathode angle θcathode great enough, the cathode electrode 114 may be formed to be in contact with the auxiliary cathode electrode 202 formed below the overhang structure layer 110. by providing an appropriate emission layer angle θOLED and common layer angle θHIL, the emission layer 112 and the common layer 204 may be formed not to be in contact with the auxiliary cathode electrode 202. By providing an appropriate common layer angle θHIL, emission layer angle θOLED and cathode angle θcathode, respectively, an expected configuration of common layer, emission layer and cathode may be provided, achieving more precise control over the corresponding layer structure.

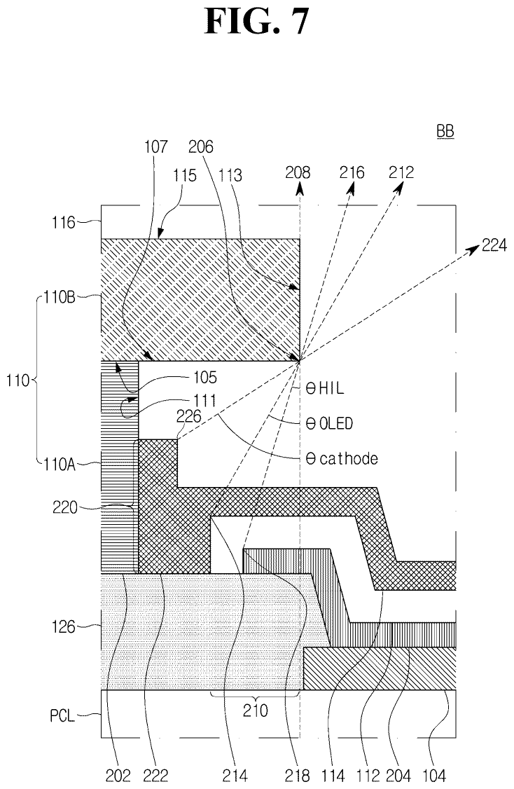

FIG. 7 is an enlarged view according to another embodiment with respect to BB region of FIG. 5. Among the components of FIG. 7, those redundant with FIG. 6 will be granted with the same reference numerals as those of FIG. 6, and detailed description thereof will be omitted.

Referring to FIG. 7, in comparison with the embodiment of FIG. 6, the auxiliary cathode electrode 202 is omitted. Alternatively, the auxiliary cathode electrode 202 may be formed of one pattern with a portion of the lower layer 110A or the lower layer 110A. In such an embodiment, the lower layer 110A of the overhang structure layer 110 may be formed of a conductive inorganic material.

The cathode electrode 114 may be formed on the emission layer 112 and one region of the bank 126. In addition, the cathode electrode 114 may be further formed to be in contact with the lower layer 110A of the overhang structure layer 110. For example, the cathode electrode 114 may be formed in the one region 220 of the side surface 111 of the lower layer 110A.

In such an embodiment, the lower layer 110A may be formed of a conductive inorganic material. In comparison with the embodiment of FIG. 6, a contact area between the cathode electrode 114 and the lower layer 110A is greater than a contact area between the cathode electrode 114 and the auxiliary cathode electrode 202. In addition, a size of the lower layer 110A is greater than that of the auxiliary cathode electrode 202. As shown in FIG. 7, a larger contact area may be achieved, even if the cathode electrode 114 is formed at the same cathode angle θcathode as in FIG. 6.

Therefore, an electrical contact between the cathode electrode 114 and the lower layer 110A may be performed more easily, and transfer of the electrical signal may be efficiently performed. As a result, the cathode electrode 114 may receive the electrical signal applied from the low potential driving voltage line PL2 more efficiently through the lower layer 110A, and the electrical reliability between the cathode electrode 114 and the low potential driving voltage line PL2 may increase.

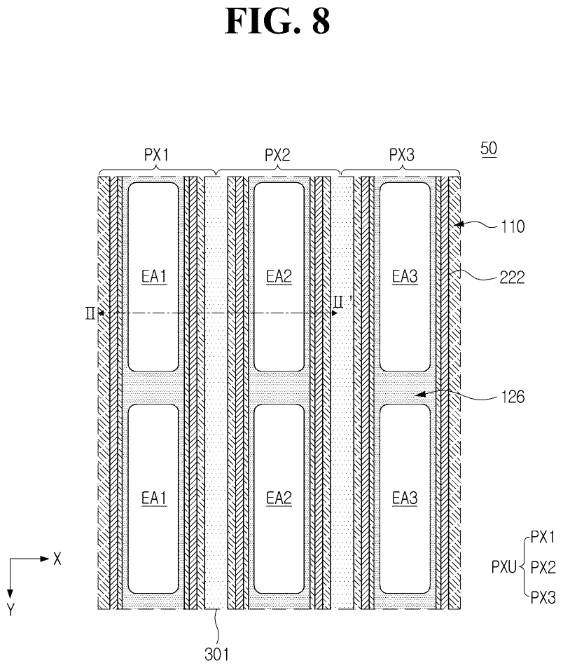

FIG. 8 is a schematic plan view of a display panel according to a first embodiment.

Referring to FIG. 8, the display panel 50 according to an embodiment may include a plurality of unit pixels PXU. Each of the unit pixel PXU may include a plurality of pixels PX1, PX2 and PX3 configured to emit colors different from one another. In an embodiment, the plurality of pixels PX1, PX2 and PX3 may display one color among red, green and blue. However, the embodiment is not limited thereto. The unit pixels may further include pixels other than the plurality of pixels PX1, PX2, and PX3. In such unit pixels, one or more pixels displaying white color may also be included, in addition to the plurality of pixels PX1, PX2, and PX3 each displaying one color among red, green, and blue. In another embodiment, the plurality of pixels PX1, PX2, and PX3 may each display one color among cyan, magenta, and yellow.

In an embodiment, the pixels PX1, PX2 and PX3 configured to emit colors different from one another may be sequentially and alternately disposed along the first direction X. The first direction may be a horizontal direction. However the embodiment is not limited thereto, e.g., the first direction may also be a vertical direction. In addition, the pixels PX1, PX2 and PX3 configured to emit the same color may be disposed along the second direction Y generally perpendicular to the first direction. The second direction may be a vertical direction. However, the embodiment is not limited thereto, e.g., the second direction may also be a horizontal direction.

Each of the pixels PX1, PX2 and PX3 may be in contact with the overhang structure layer 110 configured to define regions (hereinafter, pixel regions) of the pixels PX1, PX2 and PX3. For example, each of the pixels PX1, PX2 and PX3 may be in contact with the overhang structure layer 110 in the first direction X. In another embodiment, each of the pixels PX1, PX2 and PX3 may be in contact with the overhang structure layer 110 in the second direction Y.

Like FIG. 3, each of the pixels PX1, PX2 and PX3 may include the emission region EA1, EA2 and EA3 in correspondence therewith. Each of the emission regions EA1, EA2 and EA3 may be surrounded by the bank 126 which defines the emission regions EA1, EA2 and EA3. FIG. 8 schematically illustrates that the pixels PX1, PX2, and PX3 each include two emission regions separated from each other. For example, the pixel PX1 includes two emission regions EA1 separated from each other, the pixel PX2 includes two emission regions EA2 separated from each other, and the pixel PX3 includes two emission regions EA3 separated from each other. However, the embodiment is not limited thereto; the pixels PX1, PX2, and PX3 may each include more emission regions separated from each other.

In addition, the first cathode connection 222 may be provided while overlapping the overhang structure layer 110. In an embodiment, the first cathode connection 222 may be covered by the overhang structure layer 110 and overlap the overhang structure layer 110 on a plane.

In an embodiment of FIG. 8, the pixels PX1, PX2 and PX3 may be disposed in a stripe shape. In such a structure, each of the pixels PX1, PX2 and PX3 may be in contact with the overhang structure layer 110 in only the first direction X, and may not be in contact therewith in the second direction Y. Instead, each of the pixels PX1, PX2 and PX3 may be separated by the bank 126 in the second direction Y.

As described above with reference to FIG. 6, in an embodiment, the emission layer 112, the common layer 204 and the cathode electrode 114 may be formed by evaporation deposition using the overhang structure layer 110. In case of the dot-shape arrangement illustrated in FIG. 3, each of the pixels PX1, PX2 and PX3 may be in contact with the overhang structure layer 110 on all the four surfaces. Therefore, when forming the emission layer 112, the common layer 204 and the cathode electrode 114 by evaporation deposition, an incident angle of an evaporation source has to be adjusted with respect to all the four surfaces. In this case, a size of the evaporation deposition device and a manufacturing cost may increase, and a process yield may decrease because of increased complexity of the manufacturing process.

In case of the stripe-shape arrangement illustrated in FIG. 8, each of the pixels PX1, PX2 and PX3 may be in contact with the overhang structure layer 110 on only two surfaces. Therefore, when forming the emission layer 112, the common layer 204 and the cathode electrode 114 by evaporation deposition, an incident angle of the evaporation source may be adjusted with respect to only two directions. Therefore, a size of the evaporation deposition device and a manufacturing cost may decrease, and a process yield may increase because of low complexity of the manufacturing process.

In addition, the stripe-shape arrangement may simplify the overhang structure layer 110, and lower complexity of a device, thereby improving the manufacturing yield and reliability and quality of a product.

Referring further to FIG. 8, the display panel 50 according to an embodiment may include a second cathode connection 301 disposed to overlap the overhang structure layer 110. The second cathode connection 301 may be provided to electrically connect the auxiliary cathode electrode 202 which has been described referring to FIG. 6, and the low potential driving voltage line PL2 (FIG. 2) to each other. For example, in the second cathode connection 301, the auxiliary cathode electrode 202 may be directly connected to the low potential driving voltage line PL2, or may be indirectly connected to the low potential driving voltage line PL2 through the connection electrode 106 connected to the low potential driving voltage line PL2 and the like. Hereinafter, a case in which the auxiliary cathode electrode 202 passes through the connection electrode 106 and is connected to the low potential driving voltage line PL2 is taken as an example, but the embodiment is not limited thereto.

In an embodiment, the second cathode connection 301 may be disposed between the pixel columns adjacent to each other. Between the pixel columns adjacent to each other, the second cathode connection 301 may be elongated along the second direction Y. FIG. 8 schematically illustrates the second cathode connection 301 elongating along the second direction Y between the first pixels PX1 and the second pixels PX2 adjacent to each other, and between the second pixels PX2 and the third pixels PX3 adjacent to each other.

Such a structure of the second cathode connection 301 may follow a shape of the auxiliary cathode electrode 202 and the connection electrode 106. That is, the auxiliary cathode electrode 202 and the connection electrode 106 may be patterned to be elongated between the pixel columns adjacent to each other along the second direction Y, and may be electrically in contact with each other through a contact hole in the patterned region. As shown in FIG. 8, the second cathode connection 301 may be in a strip form, that is, the second cathode connection 301 has a length in the second direction Y greater than the width in the first direction X.

In an embodiment, a width in the first direction X (that is, along the pixel row direction) of the second cathode connection 301 is narrower than a width in the first direction X of the auxiliary cathode electrode 202. That is, a width in the first direction X of the connection electrode 106 may be narrower than the width in the first direction X of the auxiliary cathode electrode 202. With this configuration, an electrical short between the connection electrode 106 and other circuit elements disposed in the regions of the pixels PX1, PX2 and PX3 may be prevented.

In the embodiment in which the second cathode connection 301 is elongated in the second direction Y, that is, along the pixel column direction, an area of an electrical contact between the auxiliary cathode electrode 202 and the connection electrode 106 is very wide. Therefore, an IR drop phenomenon generated when the low potential driving voltage ELVSS is applied to the display panel 50 having a large area is improved, and the low potential driving voltage ELVSS (FIG. 2) having the same magnitude is stably supplied to the pixels PX1, PX2 and PX3, thereby luminance uniformity between the pixels PX1, PX2 and PX3 may be improved.

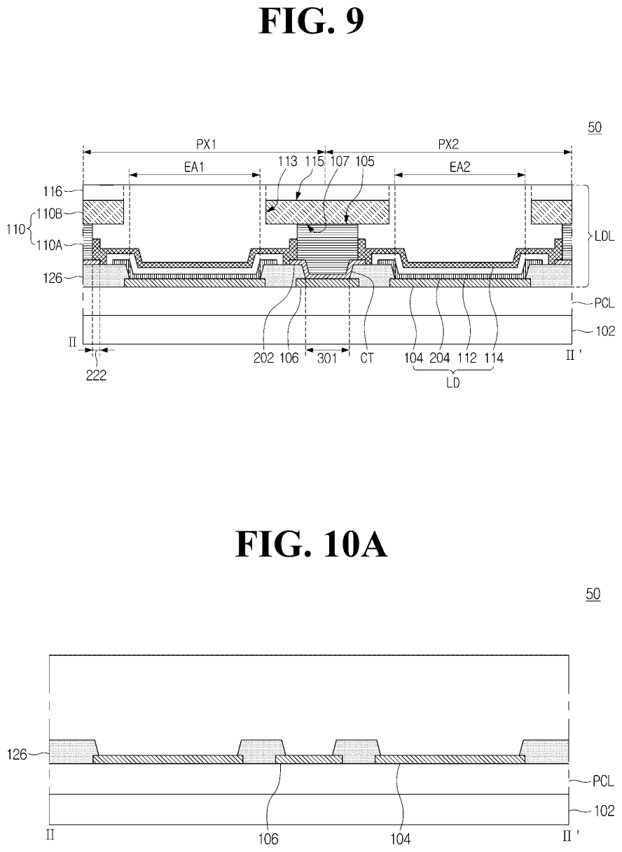

FIG. 9 is an embodiment of a cross-sectional view taken along II-II′ line in FIG. 8. Among the components of FIG. 9, those redundant with FIG. 5 will be granted with the same reference numerals as those of FIG. 5, and detailed description thereof will be omitted.

Referring to FIG. 9, the first electrode 104 may be patterned on the circuit element layer PCL. The first electrode 104 may be, for example, the anode electrode 104. The anode electrode 104 may be patterned in correspondence with each of the pixels PX1 and PX2.

The bank 126 may be formed on the anode electrode 104. The bank 126 may be disposed such that the bank 126 covers one region of the anode electrode 104, for example, an edge thereof, and exposes the remaining other region, for example, a center region. The bank 126 may be formed wide on the substrate 102. The exposed region of the anode electrode 104 not covered by the bank 126 may be defined as the emission region. In the exposed region of the anode electrode 104, the common layer 204, the emission layer 112, and the cathode electrode 114 may be sequentially stacked to be in direct contact with each other, thereby forming the light emitting element LD.

The overhang structure layer 110 may be disposed on the bank 126. The overhang structure layer 110 may be formed to define regions of each of the pixels PX1 and PX2. In addition, the auxiliary cathode electrode 202 may be further formed below the overhang structure layer 110. The auxiliary cathode electrode 202 may be interposed between the lower layer 110A of the overhang structure layer 110 and the bank 126, and at least one region 222 thereof protrudes outward of the overhang structure layer 110 to form the first cathode connection 222 in contact with the cathode electrode 114. As shown in FIG. 9, the first cathode connection 222 may be formed as a step. That is, the upper surface of the first cathode connection 222 may be higher than the upper surface of the bank 126, and the side surface of the first cathode connection 222 may be located further outward relative to the side surface 111 of the lower layer 110A of the overhang structure layer 110 and protrude from the side surface 111 of the lower layer 110A of the overhang structure layer 110, thereby forming a step.

The auxiliary cathode electrode 202 may be in contact with the connection electrode 106 formed below the bank 126 through a contact hole formed on the bank 126. Here, a region of the auxiliary cathode electrode 202 which is in contact with the connection electrode 106 may be defined as the second cathode connection 301. As illustrated in FIG. 8, in order to form the second cathode connection 301 elongated in the second direction Y, a contact hole CT may be formed in the bank 126 in a shape elongated between the pixel columns adjacent to each other.

In an embodiment, the connection electrode 106 may be formed on the same layer and formed of the same material as the anode electrode 104, but is not limited thereto. The connection electrode 106 may include a metal material having a high reflectance such as a stacked structure of aluminum (Al) and titanium (Ti)(Ti/Al/Ti), a stacked structure of aluminum (Al) and indium tin oxide (ITO)(ITO/Al/ITO), and an APC alloy. The connection electrode 106 may consist of a single layer or multiple layers, but the embodiments of the present disclosure are not limited thereto. For example, when the connection electrode 106 is formed on a different layer from that of the anode electrode 104, for example, is formed on a lower layer, the contact hole CT may be formed to penetrate one or more insulating layers interposed between the connection electrode 106 and the auxiliary cathode electrode 202.

The overhang structure layer 110 may be formed on the auxiliary cathode electrode 202 to cover the contact hole CT. In more detail, the lower layer 110A of the overhang structure layer 110 may be formed to cover the contact hole CT and the second cathode connection 301, and expose the first cathode connection 222 of the auxiliary cathode electrode 202 upward.

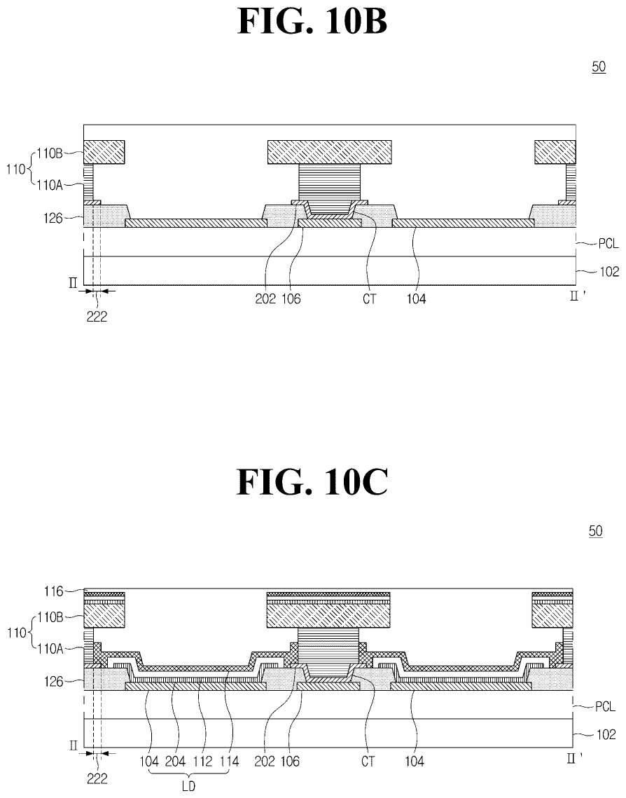

FIGS. 10A to 10E are views illustrating a method for manufacturing the display panel according to an embodiment.

Referring to FIG. 10A, the anode electrode 104 and the bank 126 may be formed on the circuit element layer PCL. The anode electrode 104 may be patterned in correspondence with the regions of each of the pixels PX1 and PX2 (FIG. 9).

In an embodiment, the low potential driving voltage line PL2 or the connection electrode 106 may be further formed on the circuit element layer PCL. The connection electrode 106 may be configured to receive the low potential driving voltage ELVSS, and may be electrically connected to the low potential driving voltage line PL2 through, for example, a contact hole of which illustration is omitted.

The bank 126 may be formed on the anode electrode 104 and the connection electrode 106. For example, a bank material may be deposited on the circuit element layer PCL, and a portion of the bank material may be removed and patterned by a mask such as a photoresist and the like. The bank 126 may be patterned to cover an edge of the anode electrode 104, and expose a center region thereof. In addition, the bank 126 may be patterned to have the contact hole CT which covers an edge of the connection electrode 106 and exposes a center region thereof. The patterning may be performed through photolithography, a digital lithography process, or a laser ablation process and the like.

Referring to FIG. 10B, the auxiliary cathode electrode 202 may be formed on the bank 126. The auxiliary cathode electrode 202 may be formed to overlap at least one region of the contact hole CT, and may be in contact with the connection electrode 106 exposed upward through the contact hole CT. For example, a material of the auxiliary cathode electrode 202 may be deposited on the bank 126, and the material of the auxiliary cathode electrode 202 may be removed from a remaining region except a region around the contact hole CT by a dry etching process or a wet etching process. Therefore, the auxiliary cathode electrode 202 may be formed not to be in contact with the anode electrode 104.

The overhang structure layer 110 may be formed on the auxiliary cathode electrode 202. In an embodiment, a material of the lower layer and a material of the upper layer may be deposited on the bank 126, and they may be patterned to have an illustrated shape through a mask such as the photoresist and the like. For example, in an embodiment, the lower layer 110A may be patterned to expose at least one region 222 of the auxiliary cathode electrode 202 formed on a lower side. In addition, the upper layer 110B may be formed to have a wider lower surface than an upper surface of the lower layer 110A so that an overhang is formed.

In an embodiment, a portion of the material of the upper layer may be removed through a dry etching process and the like so that the upper layer 110B can be formed. In addition, a portion of the material of the lower layer may be removed through a wet etching process and the like so that the lower layer 110A can be formed. In an embodiment, a resist may be a positive resist or a negative resist. At this instance, the etching selectivity and the etching process of the material of the upper layer and the material of the lower layer may be suitably selected so that overhang can be formed between the upper layer 110B and the lower layer 110A.

Referring to FIG. 10C, the common layer 204, the emission layer 112, the cathode electrode 114 and the encapsulation layer 116 of the first pixel PX1 may be formed on the bank 126 and the overhang structure layer 110. Each of the common layer 204, the emission layer 112 and the cathode electrode 114 may be formed by the evaporation deposition described with reference to FIG. 6.

Through the overhang structure layer 110, the common layer 204 and the emission layer 112 in the region of the first pixel PX1 may be formed not to be in contact with the auxiliary cathode electrode 202, and the cathode electrode 114 may be formed to be in contact with the exposed region 222 of the auxiliary cathode electrode 202. At this instance, materials of the common layer 204, the emission layer 112 and the cathode electrode 114 may be further formed on the overhang structure layer 110 and in the region of the other pixel PX2 adjacent thereto.

Referring to FIG. 10D, from a remaining other region except the region of the first pixel PX1, the common layer 204, the emission layer 112, the cathode electrode 114 and the encapsulation layer 116 may be removed through the mask such as the photoresist and the like. The common layer 204, the emission layer 112, the cathode electrode 114 and the encapsulation layer 116 may be removed by the wet etching process and the like. Therefore, the common layer 204, the emission layer 112, the cathode electrode 114 and the encapsulation layer 116 may be patterned in correspondence with the region of the first pixel PX1.

Referring to FIG. 10E, the common layer 204, the emission layer 112, the cathode electrode 114 and the encapsulation layer 116 of the second pixel PX2 may be formed and patterned on the bank 126 and the overhang structure layer 110. Each of the common layer 204, the emission layer 112, the cathode electrode 114 may be formed by the evaporation deposition described with reference to FIG. 6. In addition, through the process described with reference to FIG. 10D, the common layer 204, the emission layer 112, and the cathode electrode 114 may be patterned in correspondence with the region of the second pixel PX2.

In the embodiment illustrated in FIGS. 10A to 10E, the method for manufacture may form two pixels PX1 and PX2. The operations illustrated in FIGS. 10A to 10E may be repeated with respect to additional pixels, and may further form three or more pixels.

According to the manufacturing process as above, while the pixels PX1 and PX2 are formed in the display region AA (FIG. 1) of the display panel 50, an electrical contact between the auxiliary cathode electrode 202 and the connection electrode 106, that is, the low potential driving voltage ELVSS is formed. Therefore, an additional process for electrically connecting the auxiliary cathode electrode 202 and the low potential driving voltage ELVSS to each other is not required. In such an embodiment, the contact between the auxiliary cathode electrode 202 and the connection electrode 106 may be formed in the display region AA. That is, the second cathode connection 301 may be disposed in the display region AA in which the pixels PX1 and PX2 are disposed.

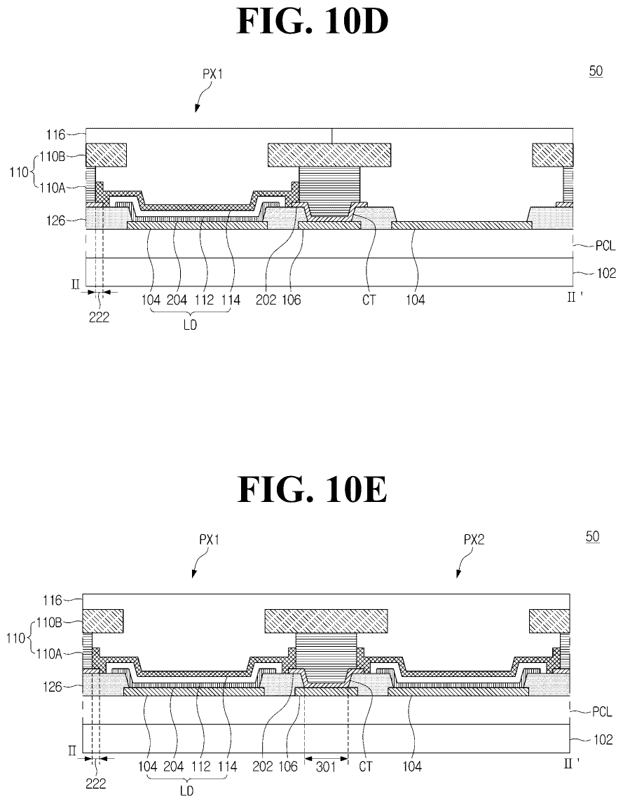

FIG. 11 is a schematic plan view of a display panel according to a second embodiment.

In comparison with the embodiment of FIG. 8, in the embodiment of FIG. 11, the second cathode connection 301 may be formed in an island form, instead of a shape extending in one direction. For example, the second cathode connection 301 may be disposed between the pixel columns adjacent to each other in the first direction X, and between the pixel rows adjacent to each other in the second direction Y.

The second cathode connection 301 in the island form may generally have a quadrangular shape as illustrated. However, the embodiment is not limited thereto, and in another embodiment, the second cathode connection 301 may have a polygonal, circular, elliptical, or irregular shape such as a quadrangular, triangular, hexagonal shape and the like.

In an embodiment, the overhang structure layer 110 may be formed such that both sides thereof are bent or curved along a circumference of the second cathode connection 301 around the second cathode connection 301. For example, the overhang structure layer 110 may extend while having a first width X1 between the pixel columns adjacent to each other, and may have a second width X2 wider than the first width X1 in a region overlapping the second cathode connection 301. As shown in FIG. 11, the side surfaces of the overhang structure layer 110 may have an outwardly protruding bending shape around the second cathode connection 301. That is, in the first direction X, the two side edges of the overhang structure layer 110 have a curved shape outwardly protruding around the second cathode connection 301. The upper layer 110B and the lower layer 110A of the overhang structure layer 110 may have a consistent bending/curved shape; for example, the side surfaces/side edges of the upper layer 110B and the side surfaces/side edges of the lower layer 110A may have a consistent bending/curved shape outwardly protruding around the second cathode connection 301. Thereby, the overhang structure layer 110 having a width in the region overlapping the second cathode connection 301 greater than the width in the region extending between the pixel columns adjacent to each other may be formed, that is, the second width X2 is greater than the first width X1.

When the overhang structure layer 110 is formed with the first width X1 which is generally narrow between the pixel columns, the region of each of the pixels PX1, PX2 and PX3 may become relatively wider. Therefore, in the region of each of the pixels PX1, PX2 and PX3, an aperture ratio at which the anode electrode 104 is exposed and areas of the emission regions EA1, EA2 and EA3 may increase, and emission efficiency and luminance may increase, thereby the image quality may be improved.

The overhang structure layer 110 may be formed to have the second width X2 which is sufficiently wide to fully cover the second cathode connection around the second cathode connection 301. With this configuration, the electrical connection between the auxiliary cathode electrode 202 and the low potential driving voltage ELVSS may be stably maintained while improving the aperture ratio of the pixels PX1, PX2 and PX3.

Meanwhile, in FIG. 11, one second cathode connection 301 is provided with respect to one or more unit pixels PXU. However, the embodiment is not limited thereto, and in another embodiment, the second cathode connection 301 may be provided for each of the pixels PX1, PX2 and PX3, may be provided for every two or more pixels PX1, PX2 and PX3, may be provided for each of the unit pixels PXU, or may be provided for every two or more unit pixels PXU.

Meanwhile, in FIG. 11, it is illustrated that the second cathode connection 301 is provided between the first pixel PX1 and the second pixel PX2, however, the embodiment is not limited thereto. The second cathode connection 301 may be provided between the second pixel PX2 and the third pixel PX3, or may be alternately provided between the first pixel PX1 and the second pixel PX2, and between the second pixel PX2 and the third pixel PX3.

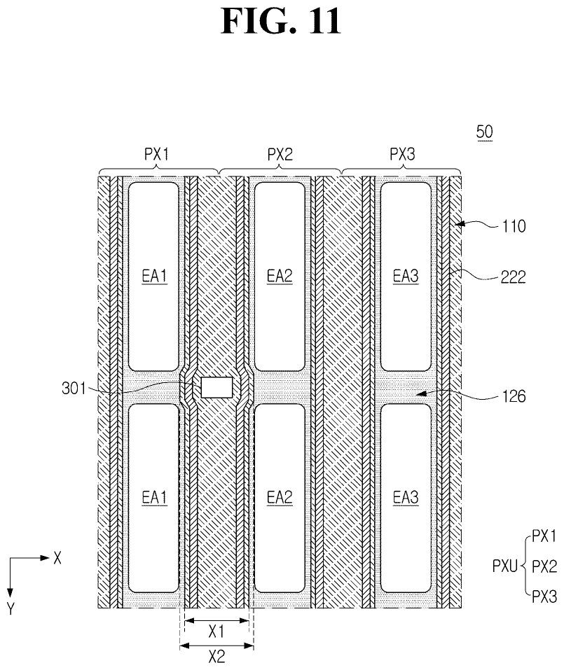

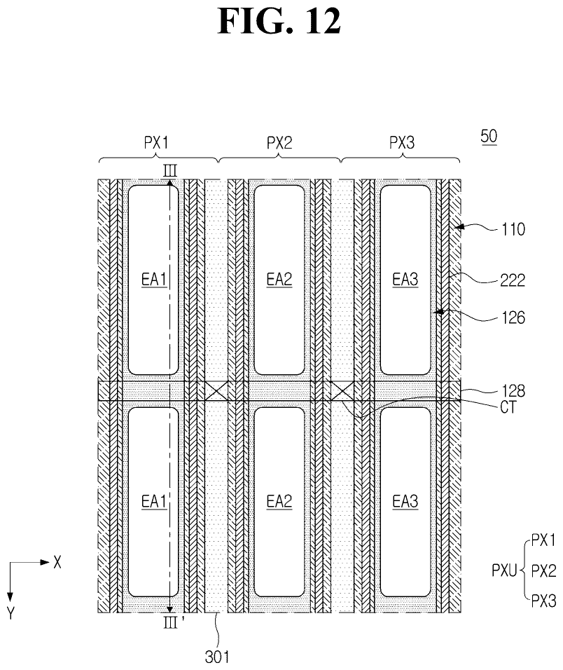

FIG. 12 is a schematic plan view of a display panel according to a third embodiment. FIG. 13 is a schematic plan view of a display panel according to a fourth embodiment.

In the display panel 50 having a stripe arrangement, the overhang structure layer 110 may be disposed between the pixel columns adjacent to each other. The overhang structure layer 110 includes the lower layer 110A and the upper layer 110B and may block an electrical connection between the pixel columns adjacent to each other.

On contrary, the overhang structure layer 110 is not formed between the pixel rows adjacent to each other, and the pixels PX1, PX2 and PX3 are divided by the bank 126. A lateral leakage current (LLC) may be generated between the pixels PX1, PX2 and PX3 in the same color disposed close to each other in the second direction Y.

The lateral leakage current may be more easily generated in the stripe arrangement, rather than in the dot-shaped arrangement illustrated in FIG. 3. In more detail, in the dot-shaped arrangement, all four surfaces are surrounded by the overhang structure layer 110, and therefore, the lateral leakage current is not generated between the pixels PX1, PX2 and PX3 adjacent to each other in the column direction and the row direction. On contrary, in the stripe-shaped arrangement, the overhang structure layer 110 is not formed between the pixel rows adjacent to each other, and the lateral leakage current may be generated.

Referring to FIGS. 12 and 13, in an embodiment, the bank 126 may be formed to have a pattern portion 128. The pattern portion 128 may include one or more patterns recessed or protruding from an upper surface of the bank 126.

As the pattern portion 128 is formed, a current path for passing through the bank 126 is elongated and a resistance in the common layer may increase. With this configuration, the lateral leakage current may be prevented between the pixel rows adjacent to each other and separated by the bank 126.

The pattern portion 128 may be formed on an upper surface of the bank 126, and may extend long between the pixel rows adjacent to each other along the first direction X. Such a pattern portion 128 may be formed such that at least one region thereof intersects the overhang structure layer 110.

When the second cathode connection 301 is formed below the overhang structure layer 110, the pattern portion 128 may be formed to intersect the second cathode connection 301. In such an embodiment, the pattern portion 128 may pass through the contact hole CT in the second cathode connection 301 and extend, as illustrated in FIG. 12, or may be formed discontinuously by being cut on both sides of the second cathode connection 301 as illustrated in FIG. 13.

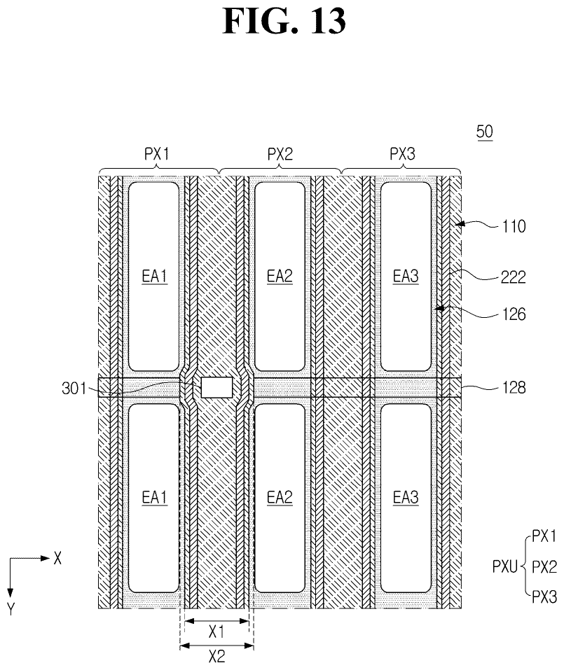

FIG. 14 is an embodiment of a cross-sectional view taken along III-III′ line illustrated in FIG. 12.

Referring to FIG. 14, the first electrode 104 may be patterned on the circuit element layer PCL. The first electrode 104 may be, for example, the anode electrode 104. The anode electrode 104 may be patterned in correspondence with each emission region EA1 in the pixels PX1.

The bank 126 may be disposed on the anode electrode 104. The bank 126 may cover one region of the anode electrode 104, for example, an edge, and expose the remaining other region, for example, a center region. The bank 126 may be formed widely on the substrate 102. The exposed region of the anode electrode 104 not covered by the bank 126 may be defined as an emission region.

The common layer 204, the emission layer 112 and the cathode electrode 114 may be sequentially stacked in the exposed region of the anode electrode 104 and in direct contact with each other in the exposed region of the anode electrode 104, thereby forming the light emitting element LD. The common layer 204, the emission layer 112 and the cathode electrode 114 may be continuously formed between the pixel rows in the same color and adjacent to each other. In particular, the emission layer 112 may be elongated in the second direction Y in correspondence with the pixel column in which the pixels PX1 in the same color are disposed.

The bank 126 may include the pattern portion 128. The bank 126 may include, for example, one or more patterns protruding from the upper surface of the bank 126. In the illustrated embodiment, the pattern portion 128 may include only one protruding pattern, but the embodiment is not limited thereto.

In an embodiment, the pattern portion 128 may be formed by gradually adjusting a height of the bank 126 using a half-tone mask. However, the method for forming the pattern portion 128 is not limited thereto, and the pattern portion 128 may be formed through an additional deposition process after forming the bank 126.

In comparison with a case in which the pattern portion 128 is not formed, when the pattern portion 128 is formed, a length of the current path between the pixels PX1 adjacent to each other which passes through a surface of the bank 126 increases. Therefore, the electrical resistance between the pixels PX1 adjacent to each other increases, and the lateral leakage current may be prevented or at least, reduced. As shown in FIG. 14, the protruded pattern portion 128 has inclined side surfaces, thereby having a longer path length compared to the case in which the patterned portion 128 is not formed.

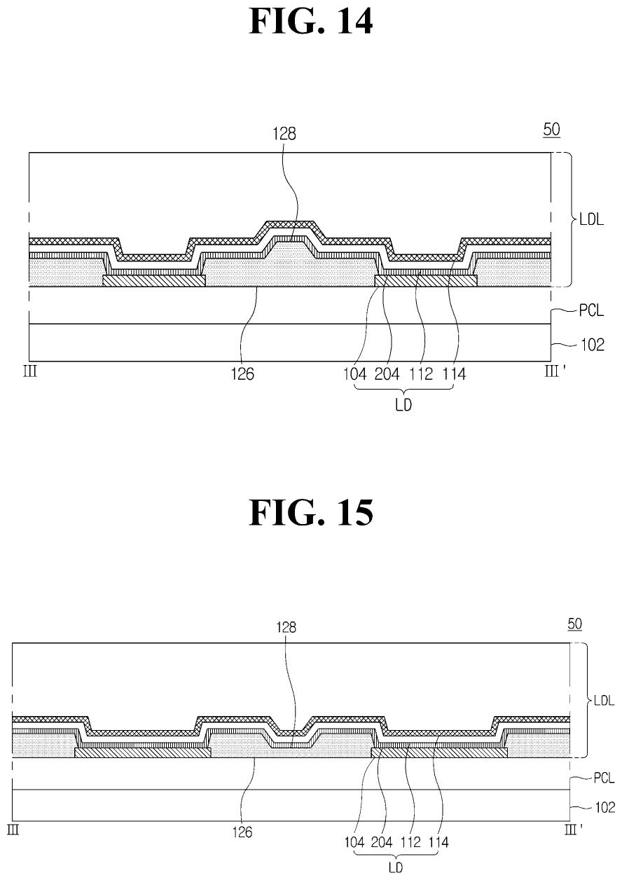

FIG. 15 is another embodiment of a cross-sectional view taken along III-III′ line illustrated in FIG. 12.

Referring to FIG. 15, the pattern portion 128 according to an embodiment may include one or more patterns recessed from an upper surface of the bank 126. That is, the pattern portion 128 may include at least one trench. In the illustrated embodiment, the pattern portion 128 may include one trench only, but the embodiment is not limited thereto.

In an embodiment, the pattern portion 128 may be formed by partially adjusting the height of the bank 126 using the half-tone mask. However, the method for forming the pattern portion 128 is not limited thereto, and the pattern portion 128 may be formed through an additional etching or patterning process after forming the bank 126.

A depth of the trench forming the pattern portion 128 may be equal to or smaller than a thickness of the bank 126. For example, the trench may be formed by partially removing a portion of the thickness of the bank 126. Alternatively, the trench may be formed in a hole shape penetrating the bank 126, by removing the entire thickness of the bank 126.

In an embodiment, the pattern portion 128 may be formed by the same process as a process for forming the contact hole CT (FIG. 9) for forming the second cathode connection 301 (FIG. 9). That is, the pattern portion 128 and the contact hole CT may be formed by one process. When depths of the contact hole CT and the pattern portion 128 are different, the contact hole CT and the pattern portion 128 may be formed simultaneously using the half-tone mask. However, the process for forming the pattern portion 128 is not limited to the description above.

As shown in FIG. 15, similar as the embodiment in FIG. 14 (protruded pattern portion 128), the recessed pattern portion 128 also has inclined side surfaces, thereby having a longer path length compared to the case in which the patterned portion 128 is not formed, and thereby increasing a length of the current path between the pixels PX1 adjacent to each other which passes through a surface of the bank 126, increasing the electrical resistance between the pixels PX1 adjacent to each other, and preventing or at least reducing the lateral leakage current.

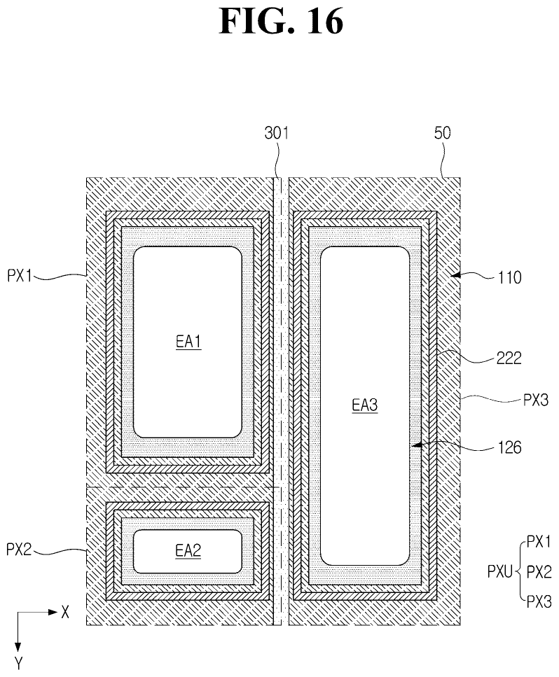

FIG. 16 is a schematic plan view of a display panel according to a fifth embodiment.

Referring to FIG. 16, the display panel 50 according to an embodiment may include a plurality of unit pixels PXU. Each of the unit pixel PXU may include a plurality of pixels PX1, PX2 and PX3 configured to emit colors different from one another. In an embodiment, the plurality of pixels PX1, PX2 and PX3 may display one color among red, green and blue. However, the embodiment is not limited thereto. The unit pixels may further include pixels other than the plurality of pixels PX1, PX2, and PX3. In such unit pixels, one or more pixels displaying white color may also be included, in addition to the plurality of pixels PX1, PX2, and PX3 each displaying one color among red, green, and blue. In another embodiment, the plurality of pixels PX1, PX2, and PX3 may each display one color among cyan, magenta, and yellow.

In an embodiment, the first pixel PX1 and the third pixel PX3 may be alternately disposed along the first direction X. In addition, the second pixel PX2 and the third pixel PX3 may be alternately disposed along the first direction X. The first direction may be a horizontal direction. However the embodiment is not limited thereto, e.g., the first direction may also be a vertical direction.

The first pixel PX1 and the second pixel PX2 may be alternately disposed along the second direction Y generally perpendicular to the first direction X. The third pixel PX3 may be disposed along the second direction Y. That is, the display panel 50 may include a first pixel column in which the first pixel PX1 and the second pixel PX2 are alternately disposed, and a second pixel column in which the third pixel PX3 is disposed. An order of the first pixel column and the second pixel column in the unit pixel PXU may be changed from what is illustrated. In addition to the configuration as shown in FIG. 16, other suitable configurations of the first and second pixel columns may be included. For example, the third pixel PX3 may be disposed in the first pixel column, and the first pixel PX1 and the second pixel PX2 may be alternately disposed in the second pixel column. The second direction may be a vertical direction. However, the embodiment is not limited thereto, e.g., the second direction may also be a horizontal direction.

Each of pixels PX1, PX2 and PX3 may be surrounded by the overhang structure layer 110 which defines the regions of the pixels PX1, PX2 and PX3 (hereinafter, the pixel regions). The exposed region not covered by the overhang structure layer 110 may be defined as the pixel region of each of the pixels.

Each of the pixels PX1, PX2 and PX3 may include the emission region EA1, EA2 and EA3 in correspondence therewith. Each of the emission regions EA1, EA2 and EA3 may be a region in which the anode electrode, the emission layer and the cathode electrode are in contact with each other and stacked.

Each of the emission regions EA1, EA2 and EA3 may be surrounded by the bank 126 which defines the emission regions EA1, EA2 and EA3. For example, the bank 126 may be formed on the anode electrode, and may include an opening exposing one region of the anode electrode. One region of the anode electrode not covered by the bank 126 and exposed may be defined as the emission regions EA1, EA2 and EA3.

In an embodiment, the first cathode connection 222 may be provided to overlap the overhang structure layer 110. The first cathode connection 222 may be provided to electrically connect the cathode electrode and the auxiliary cathode electrode of the light emitting element LD.

The display panel 50 according to an embodiment may include the second cathode connection 301 disposed to overlap the overhang structure layer 110. The second cathode connection 301 may be provided to electrically connect the auxiliary cathode electrode 202 which has been described referring to FIG. 6, and the low potential driving voltage line PL2 to each other. For example, in the second cathode connection 301, the auxiliary cathode electrode 202 may be directly connected to the low potential driving voltage line PL2, or may be indirectly connected to the low potential driving voltage line PL2 through the connection electrode 106 connected to the low potential driving voltage line PL2 and the like.

In an embodiment, the second cathode connection 301 may be elongated between the pixels PX1, PX2 and PX3 along the second direction Y. For example, the second cathode connection 301 may be elongated between the first pixel PX1 and the third pixel PX3 adjacent to each other in the first direction X, and between the second pixel PX2 and the third pixel PX3 adjacent to each other along the second direction Y.

In another embodiment, the second cathode connection 301 may be elongated between the pixels PX1, PX2 and PX3 in the first direction X. For example, the second cathode connection 301 may be elongated between the first pixel PX1 and the second pixel PX2 adjacent to each other in the second direction Y and between the third pixels PX3 adjacent to each other along the first direction X.

Such a structure of the second cathode connection 301 may follow a shape of the auxiliary cathode electrode 202. That is, the auxiliary cathode electrode 202 may be patterned to be elongated between the pixels PX1, PX2 and PX3 adjacent to each other along the second direction Y, and may be in contact with the connection electrode 106 in the patterned region. As shown in FIG. 16, the second cathode connection 301 may be in a strip form, that is, the second cathode connection 301 has a length in the second direction Y greater than the width in the first direction X.

In an embodiment, the width in the first direction X of the second cathode connection 301 is narrower than the width in the first direction X of the auxiliary cathode electrode 202. That is, the width in the first direction X of the connection electrode 106 may be narrower than the width in the first direction X of the auxiliary cathode electrode 202. With this configuration, an electrical short between the connection electrode 106 and other circuit elements disposed in the regions of the pixels PX1, PX2 and PX3 may be prevented.

In the embodiment in which the second cathode connection 301 is elongated in the second direction Y, that is, along the pixel column direction, an area of an electrical contact between the auxiliary cathode electrode 202 and the connection electrode 106 is very wide. Therefore, the IR drop phenomenon generated when the low potential driving voltage ELVSS is applied to the display panel 50 having a large area is improved, and the low potential driving voltage ELVSS (FIG. 2) having the same magnitude is stably supplied to the pixels PX1, PX2 and PX3, thereby luminance uniformity between the pixels PX1, PX2 and PX3 may be improved.

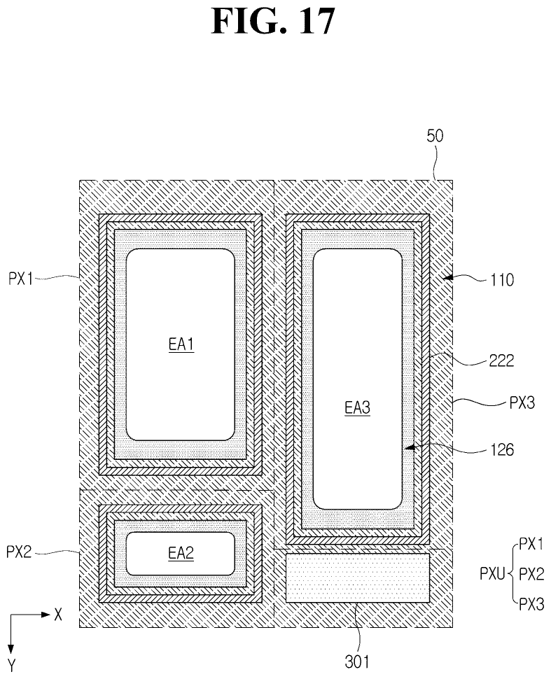

FIG. 17 is a schematic plan view of a display panel according to a sixth embodiment.

In comparison with the embodiment of FIG. 16, in the embodiment of FIG. 17, the second cathode connection 301 may be formed in the island form, instead of a shape extending in a column direction. At this instance, the second cathode connection 301 may be formed to overlap the overhang structure layer 110 around the pixels PX1, PX2 and PX3. In FIG. 17, the second cathode connection 301 is illustrated to be formed on one side of the third pixel PX3, but the embodiment is not limited thereto.

In an embodiment, one of the second cathode connection 301 may be provided for every one unit pixel PXU. However, the embodiment is not limited thereto, and in another embodiment, only one of the second cathode connection 301 may be provided for every one pixel PX1, PX2 and PX3, or may be provided for every two or more pixels PX1, PX2 and PX3, or may be provided for every one unit pixel PXU, or may be provided for every two or more unit pixels PXU.

The second cathode connection 301 may have generally a quadrangular shape as illustrated. However, the embodiment is not limited thereto and in another embodiment, the second cathode connection 301 may have a polygonal, circular, elliptical, or irregular shape such as a quadrangular, triangular, hexagonal shape and the like.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
an anode electrode formed on the substrate;
a connection electrode formed on the substrate and electrically connected to a low potential driving voltage;
a bank formed on the anode electrode and the connection electrode and exposing at least one region of the anode electrode;
an emission layer disposed on the anode electrode;
a cathode electrode formed on the emission layer;
an overhang structure layer disposed on the bank and comprising a lower layer and an upper layer; and
a cathode connection overlapping the overhang structure layer and configured to electrically connect the cathode electrode and the connection electrode to each other.

2. The display device of claim 1, further comprising:
an auxiliary cathode electrode interposed between the bank and the overhang structure layer and having at least one region connected to the cathode electrode,
wherein the auxiliary cathode electrode is connected to the connection electrode through a contact hole formed on the bank on the cathode connection.

3. The display device of claim 2,
further comprising a plurality of pixels provided on the substrate,
wherein the plurality of pixels is disposed in a stripe form, and
wherein the overhang structure layer is formed in a shape extending between pixel columns adjacent to each other along a pixel column direction.

4. The display device of claim 3,
wherein the cathode connection is formed in a shape extending between the pixel columns adjacent to each other along the pixel column direction.

5. The display device of claim 3,
wherein the cathode connection is formed in an island form between the pixel columns adjacent to each other.

6. The display device of claim 5,
wherein the overhang structure layer has a first width between the pixel columns adjacent to each other and extends along the pixel column direction, and
wherein the overhang structure layer has a second width greater than the first width on the cathode connection.

7. The display device of claim 3,
wherein the bank comprises a pattern portion in which at least one pattern formed by protruding from or being recessed on an upper surface is formed, and
wherein the pattern portion is formed in a shape extending between pixel rows adjacent to each other.

8. The display device of claim 2,
further comprising a plurality of pixels provided on the substrate,
wherein the plurality of pixels is disposed in a dot form,
wherein the overhang structure layer is formed to surround each of the pixels, and
wherein the cathode connection is formed in an elongated shape extending between a plurality of pixels.

9. The display device of claim 8,
wherein the plurality of pixels is disposed in a dot form,
wherein the overhang structure layer is formed to surround each of the pixels,
wherein the plurality of pixels is divided into a plurality of unit pixels, each of which comprises pixels emitting in a color different from one another, and
wherein one cathode connection is disposed in every unit pixel.

10. The display device of claim 1,
wherein the lower layer is formed of a conductive inorganic material, and comes into contact with the connection electrode through a contact hole formed on the bank on the cathode connection, and
wherein the cathode electrode is formed such that at least one region thereof comes into contact with the lower layer.

11. The display device of claim 1,
wherein a lower surface of the upper layer protrudes more outward than an upper surface of the lower layer.

12. A display device, comprising:
a plurality of pixels disposed on a substrate;
a bank formed on the substrate and configured to define an emission region of each of the plurality of pixels;
an overhang structure layer formed on the bank; and
a connection electrode overlapping the overhang structure layer and electrically connected to a low potential driving voltage; and
an auxiliary cathode electrode interposed between the bank and the overhang structure layer and in contact with the connection electrode through a contact hole formed on the bank on a cathode connection,
wherein each of the plurality of pixels comprises:
an anode electrode;
an emission layer disposed on the anode electrode; and
a cathode electrode disposed on the emission layer and electrically connected to the low potential driving voltage through the auxiliary cathode electrode, and
wherein the cathode connection is formed in a stripe or an island form.

13. The display device of claim 12,
wherein the plurality of pixels is disposed in a stripe form, and
wherein the cathode connection is formed in a stripe form extending between pixel columns adjacent to each other along a pixel column direction, or in an island form between the pixel columns adjacent to each other.

14. The display device of claim 13,
wherein when the cathode connection is formed in the island form, the overhang structure layer has a first width between the pixel columns adjacent to each other, extends along the pixel column direction, and has a second width greater than the first width in the region overlapping the cathode connection.

15. The display device of claim 13,
wherein the bank comprises a pattern portion in which at least one pattern formed by protruding from or being recessed on an upper surface is formed, and
wherein the pattern portion is formed in a shape extending between pixel rows adjacent to each other.

16. The display device of claim 12,
wherein the plurality of pixels is disposed in a dot form,
wherein the overhang structure layer is formed to surround each of the pixels, and
wherein the cathode connection is formed in an elongated shape extending between a plurality of pixels.

17. The display device of claim 12,
wherein the plurality of pixels is disposed in a dot form,
wherein the overhang structure layer is formed to surround each of the pixels,
wherein the plurality of pixels is divided into a plurality of unit pixels, each of which comprises pixels emitting in a color different from one another, and
wherein one cathode connection is disposed in every unit pixel.

18. The display device of claim 15,
wherein the cathode connection is formed in a stripe form extending between pixel columns adjacent to each other along a pixel column direction, and intersects the pattern portion at the contact hole.

19. The display device of claim 15,
wherein the cathode connection is formed in an island form between the pixel columns adjacent to each other, the pattern portion is formed discontinuously by being cut on both sides of the cathode connection.

20. A display device, comprising:
a substrate;
a plurality of pixels disposed on the substrate in a stripe form;
a connection electrode formed on the substrate and electrically connected to a low potential driving voltage;
a bank formed on the substrate and configured to expose an emission region of each of the plurality of pixels; and
an overhang structure layer formed on the bank;
wherein the bank comprises a pattern portion extended in a first direction;
wherein the overhang structure layer is configured to extend between adjacent pixels among the plurality of pixels in a second direction perpendicular to the first direction, and intersects the pattern portion.
